(19) United States
(12) Patent Application Publication
(10) Pub. No.: US 2026/0059771 A1
(43) Pub. Date: Feb. 26, 2026

(54) MEMORY DEVICE

(71) Applicant: Kioxia Corporation, Tokyo (JP)

(72) Inventors: Masayoshi TAGAMI, Kuwana Mie (JP); Keisuke NAKATSUKA, Kuwana Mie (JP); Yefei HAN, Yokohama Kanagawa (JP); Shoichi MIYAZAKI, Yokkaichi Mie (JP); Takayuki ISHIKAWA, Yokkaichi Mie (JP)

(73) Assignee: Kioxia Corporation, Tokyo (JP)

(21) Appl. No.: 19/073,089

(22) Filed: Mar. 7, 2025

(30) Foreign Application Priority Data
Aug. 26, 2024 (JP) 2024-144201

(51) Int. Cl. H10B 80/00; H01L 23/00; H01L 25/065; H01L 25/18; H10B 43/27

(52) U.S. Cl. CPC H10B 80/00; H01L 24/08; H01L 25/0657; H01L 25/18; H10B 43/27; H01L 2224/08145; H01L 2924/1431; H01L 2924/14511

(57) ABSTRACT

A semiconductor device includes a substrate, first and second semiconductor layers arranged in this order apart from each other in a first direction; first wiring layers arranged apart from each other in the first direction between the substrate and the first semiconductor layer and including a first layer; second wiring layers arranged apart from each other in the first direction between the first and second semiconductor layers and including a second layer; first and second memory pillars extending in the first direction and having portions that intersect the respective first and second wiring layers and function as memory cells; and a first contact extending in the first direction to intersect with the first wiring layers, being in contact with the first layer, being insulated from the first wiring layers excluding the first layer and the first semiconductor layer, and electrically connecting the substrate and the second layer.

### CROSS-REFERENCE TO RELATED APPLICATION

This application is based upon and claims the benefit of priority from Japanese Patent Application No. 2024-144201, filed Aug. 26, 2024, the entire contents of which are incorporated herein by reference.

### FIELD

Embodiments described herein relate generally to a memory device.

### BACKGROUND

A NAND flash memory is known as a memory device capable of storing data in a non-volatile manner. In a memory device such as a NAND flash memory, a three-dimensional memory structure is adopted for high integration and large capacity.

### BRIEF DESCRIPTION OF DRAWINGS

FIG. 1 is a block diagram illustrating an example of a configuration of a memory system including a memory device according to a first embodiment.

FIG. 2 is a perspective view illustrating an outline of a bonding structure of the memory device according to the first embodiment.

FIG. 3 is a circuit diagram illustrating an example of a circuit configuration of a memory cell array included in the memory device according to the first embodiment.

FIG. 4 is a plan view illustrating an example of a planar layout of the memory cell array included in the memory device according to the first embodiment.

FIG. 5 is a plan view corresponding to a region V in FIG. 4 and illustrating an example of a planar layout of the memory cell array included in the memory device according to the first embodiment.

FIG. 6 is a cross-sectional view taken along a line VI-VI in FIG. 5 and illustrating an example of a cross-sectional structure of the memory device according to the first embodiment.

FIG. 7 is a cross-sectional view taken along a line VII-VII in FIG. 5 and illustrating an example of a cross-sectional structure of the memory device according to the first embodiment.

FIG. 8 is a cross-sectional view taken along a line VIII-VIII in FIG. 6 and illustrating an example of a cross-sectional structure of a memory pillar included in the memory device according to the first embodiment.

FIG. 9 is a cross-sectional view taken along a line IX-IX in FIG. 6 and illustrating an example of a cross-sectional structure of a contact included in the memory device according to the first embodiment.

FIG. 10 is a cross-sectional view illustrating an example of a cross-sectional structure in a process of manufacturing the memory device according to the first embodiment.

FIG. 11 is a cross-sectional view illustrating an example of a cross-sectional structure in the process of manufacturing the memory device according to the first embodiment.

FIG. 12 is a cross-sectional view illustrating an example of a cross-sectional structure in the process of manufacturing the memory device according to the first embodiment.

FIG. 13 is a cross-sectional view illustrating an example of a cross-sectional structure in the process of manufacturing the memory device according to the first embodiment.

FIG. 14 is a cross-sectional view illustrating an example of a cross-sectional structure in the process of manufacturing the memory device according to the first embodiment.

FIG. 15 is a cross-sectional view illustrating an example of a cross-sectional structure in the process of manufacturing the memory device according to the first embodiment.

FIG. 16 is a cross-sectional view illustrating an example of a cross-sectional structure in the process of manufacturing the memory device according to the first embodiment.

FIG. 17 is a cross-sectional view illustrating an example of a cross-sectional structure in the process of manufacturing the memory device according to the first embodiment.

FIG. 18 is a cross-sectional view illustrating an example of a cross-sectional structure in the process of manufacturing the memory device according to the first embodiment.

FIG. 19 is a cross-sectional view illustrating an example of a cross-sectional structure in the process of manufacturing the memory device according to the first embodiment.

FIG. 20 is a cross-sectional view illustrating an example of a cross-sectional structure in the process of manufacturing the memory device according to the first embodiment.

FIG. 21 is a plan view illustrating an example of a planar layout of a memory cell array included in a memory device according to a modification of the first embodiment.

FIG. 22 is a plan view corresponding to a region XXII in FIG. 21 and illustrating an example of a planar layout of the memory cell array included in the memory device according to the modification of the first embodiment.

FIG. 23 is a cross-sectional view taken along a line XXIII-XXIII in FIG. 22 and illustrating an example of a cross-sectional structure of the memory device according to the modification of the first embodiment.

FIG. 24 is a plan view illustrating an example of a planar layout of a memory cell array included in a memory device according to a second embodiment.

FIG. 25 is a cross-sectional view taken along a line XXV-XXV in FIG. 24 and illustrating an example of a cross-sectional structure of the memory device according to the second embodiment.

FIG. 26 is a cross-sectional view taken along a line XXVI-XXVI in FIG. 24 and illustrating an example of a cross-sectional structure of the memory device according to the second embodiment.

FIG. 27 is a cross-sectional view taken along a line XXVII-XXVII in FIG. 25 and illustrating an example of a cross-sectional structure of a contact included in the memory device according to the second embodiment.

FIG. 28 is a cross-sectional view illustrating an example of a cross-sectional structure in a process of manufacturing the memory device according to the second embodiment.

FIG. 29 is a cross-sectional view illustrating an example of a cross-sectional structure in the process of manufacturing the memory device according to the second embodiment.

FIG. 30 is a cross-sectional view illustrating an example of a cross-sectional structure in the process of manufacturing the memory device according to the second embodiment.

FIG. 31 is a cross-sectional view illustrating an example of a cross-sectional structure in the process of manufacturing the memory device according to the second embodiment.

FIG. 32 is a cross-sectional view illustrating an example of a cross-sectional structure in the process of manufacturing the memory device according to the second embodiment.

FIG. 33 is a cross-sectional view illustrating an example of a cross-sectional structure in the process of manufacturing the memory device according to the second embodiment.

FIG. 34 is a cross-sectional view illustrating an example of a cross-sectional structure in the process of manufacturing the memory device according to the second embodiment.

FIG. 35 is a cross-sectional view illustrating an example of a cross-sectional structure in the process of manufacturing the memory device according to the second embodiment.

FIG. 36 is a cross-sectional view illustrating an example of a cross-sectional structure in the process of manufacturing the memory device according to the second embodiment.

FIG. 37 is a cross-sectional view illustrating an example of a cross-sectional structure in the process of manufacturing the memory device according to the second embodiment.

FIG. 38 is a cross-sectional view illustrating an example of a cross-sectional structure of a memory device according to a first modification of the second embodiment.

FIG. 39 is a cross-sectional view illustrating an example of a cross-sectional structure in a process of manufacturing the memory device according to the first modification of the second embodiment.

FIG. 40 is a cross-sectional view illustrating an example of a cross-sectional structure in the process of manufacturing the memory device according to the first modification of the second embodiment.

FIG. 41 is a cross-sectional view illustrating an example of a cross-sectional structure in the process of manufacturing the memory device according to the first modification of the second embodiment.

FIG. 42 is a cross-sectional view illustrating an example of a cross-sectional structure in the process of manufacturing the memory device according to the first modification of the second embodiment.

FIG. 43 is a cross-sectional view illustrating an example of a cross-sectional structure in the process of manufacturing the memory device according to the first modification of the second embodiment.

FIG. 44 is a cross-sectional view illustrating an example of a cross-sectional structure of a memory device according to a second modification of the second embodiment.

FIG. 45 is a cross-sectional view illustrating an example of a cross-sectional structure in a process of manufacturing the memory device according to the second modification of the second embodiment.

FIG. 46 is a cross-sectional view illustrating an example of a cross-sectional structure in the process of manufacturing the memory device according to the second modification of the second embodiment.

FIG. 47 is a cross-sectional view illustrating an example of a cross-sectional structure in the process of manufacturing the memory device according to the second modification of the second embodiment.

FIG. 48 is a cross-sectional view illustrating an example of a cross-sectional structure in the process of manufacturing the memory device according to the second modification of the second embodiment.

FIG. 49 is a cross-sectional view illustrating an example of a cross-sectional structure in the process of manufacturing the memory device according to the second modification of the second embodiment.

FIG. 50 is a cross-sectional view illustrating an example of a cross-sectional structure in the process of manufacturing the memory device according to the second modification of the second embodiment.

FIG. 51 is a cross-sectional view illustrating an example of a cross-sectional structure of a memory device according to a third modification of the second embodiment.

FIG. 52 is a cross-sectional view illustrating an example of a cross-sectional structure in a process of manufacturing the memory device according to the third modification of the second embodiment.

FIG. 53 is a cross-sectional view illustrating an example of a cross-sectional structure in the process of manufacturing the memory device according to the third modification of the second embodiment.

FIG. 54 is a cross-sectional view illustrating an example of a cross-sectional structure in the process of manufacturing the memory device according to the third modification of the second embodiment.

FIG. 55 is a cross-sectional view illustrating an example of a cross-sectional structure in the process of manufacturing the memory device according to the third modification of the second embodiment.

FIG. 56 is a cross-sectional view illustrating an example of a cross-sectional structure in the process of manufacturing the memory device according to the third modification of the second embodiment.

FIG. 57 is a cross-sectional view illustrating an example of a cross-sectional structure of a memory device according to a fourth modification of the second embodiment.

FIG. 58 is a cross-sectional view illustrating an example of a cross-sectional structure in a process of manufacturing the memory device according to the fourth modification of the second embodiment.

FIG. 59 is a cross-sectional view illustrating an example of a cross-sectional structure in the process of manufacturing the memory device according to the fourth modification of the second embodiment.

FIG. 60 is a cross-sectional view illustrating an example of a cross-sectional structure in the process of manufacturing the memory device according to the fourth modification of the second embodiment.

FIG. 61 is a cross-sectional view illustrating an example of a cross-sectional structure in the process of manufacturing the memory device according to the fourth modification of the second embodiment.

FIG. 62 is a cross-sectional view illustrating an example of a cross-sectional structure in the process of manufacturing the memory device according to the fourth modification of the second embodiment.

FIG. 63 is a cross-sectional view illustrating an example of a cross-sectional structure in the process of manufacturing the memory device according to the fourth modification of the second embodiment.

FIG. 64 is a cross-sectional view illustrating an example of a cross-sectional structure of a memory device according to a fifth modification of the second embodiment.

FIG. 65 is a cross-sectional view illustrating an example of a cross-sectional structure in a process of manufacturing the memory device according to the fifth modification of the second embodiment.

FIG. 66 is a cross-sectional view illustrating an example of a cross-sectional structure in the process of manufacturing the memory device according to the fifth modification of the second embodiment.

FIG. 67 is a cross-sectional view illustrating an example of a cross-sectional structure in the process of manufacturing the memory device according to the fifth modification of the second embodiment.

FIG. 68 is a cross-sectional view illustrating an example of a cross-sectional structure of a memory device according to a sixth modification of the second embodiment.

FIG. 69 is a cross-sectional view illustrating an example of a cross-sectional structure in a process of manufacturing the memory device according to the sixth modification of the second embodiment.

FIG. 70 is a cross-sectional view illustrating an example of a cross-sectional structure in the process of manufacturing the memory device according to the sixth modification of the second embodiment.

FIG. 71 is a cross-sectional view illustrating an example of a cross-sectional structure in the process of manufacturing a memory device according to the sixth modification of the second embodiment.

FIG. 72 is a cross-sectional view illustrating an example of a cross-sectional structure in the process of manufacturing the memory device according to the sixth modification of the second embodiment.

FIG. 73 is a cross-sectional view illustrating an example of a cross-sectional structure of a memory device according to a seventh modification of the second embodiment.

FIG. 74 is a cross-sectional view illustrating an example of a cross-sectional structure in a process of manufacturing the memory device according to the seventh modification of the second embodiment.

FIG. 75 is a cross-sectional view illustrating an example of a cross-sectional structure in the process of manufacturing the memory device according to the seventh modification of the second embodiment.

FIG. 76 is a cross-sectional view illustrating an example of a cross-sectional structure in the process of manufacturing the memory device according to the seventh modification of the second embodiment.

FIG. 77 is a cross-sectional view illustrating an example of a cross-sectional structure in the process of manufacturing the memory device according to the seventh modification of the second embodiment.

### DETAILED DESCRIPTION

In general, according to one embodiment, a memory device includes a substrate, a first semiconductor layer, and a second semiconductor layer arranged in this order apart from each other in a first direction; a plurality of first wiring layers arranged apart from each other in the first direction between the substrate and the first semiconductor layer and including a first layer; a plurality of second wiring layers arranged apart from each other in the first direction between the first semiconductor layer and the second semiconductor layer and including a second layer; a first memory pillar extending in the first direction and having portions that intersect the respective first wiring layers and function as memory cells; a second memory pillar extending in the first direction and having portions that intersect the respective second wiring layers and function as memory cells; and a first contact extending in the first direction so as to intersect with the first wiring layers, reaching the first semiconductor layer, being in contact with the first layer, being electrically insulated from the first wiring layers excluding the first layer and the first semiconductor layer, and electrically connecting the substrate and the second layer.

Hereinafter, embodiments will be described with reference to the drawings. Dimensions and ratios of the drawings are not necessarily the same as actual ones.

In the following description, components having substantially the same functions and configurations are denoted by the same reference numerals. In a case where the components having similar configurations are particularly distinguished from each other, different characters or numbers may be added to the end of the same reference numeral.

### 1. First Embodiment

### 1.1 Configuration

### 1.1.1 Configuration of Memory System

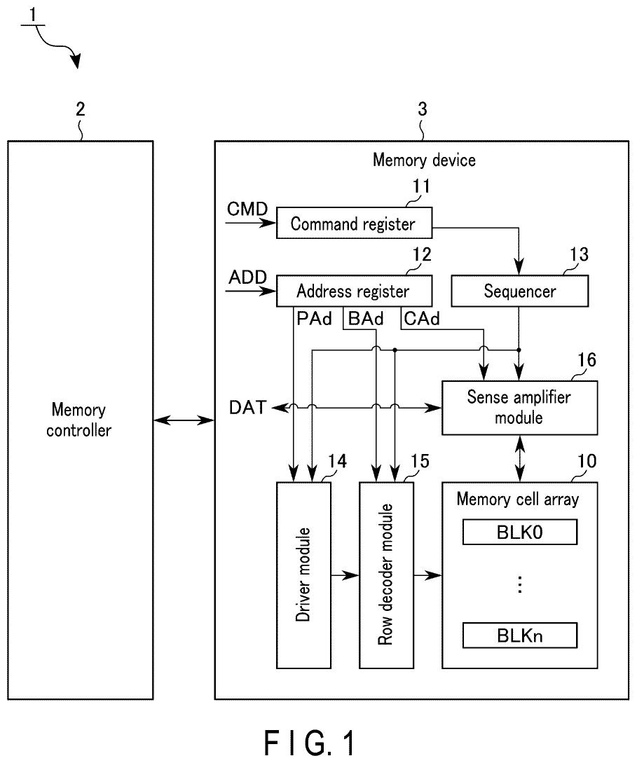

FIG. 1 is a block diagram illustrating an example of a configuration of a memory system including a memory device according to a first embodiment. A memory system 1 is a storage device configured to be connected to an external host (not illustrated). The memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data, which is requested by the host to write, to the memory device 3. In addition, the memory controller 2 reads data, which is requested by the host to read, from the memory device 3 and transmits the data to the host.

The memory device 3 is a non-volatile memory. The memory device 3 is, for example, a NAND flash memory. The memory device 3 stores data in a non-volatile manner.

Communication between the memory controller 2 and the memory device 3 conforms to, for example, a single data rate (SDR) interface, a toggle double data rate (DDR) interface, or an open NAND flash interface (ONFI).

### 1.1.2 Configuration of Memory Device

With reference to the block diagram illustrated in FIG. 1, an internal configuration of the memory device according to the first embodiment will be described. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer equal to or greater than one). The number of blocks BLK included in the memory cell array 10 may be one. The block BLK is a set of a plurality of memory cells. The block BLK is used, for example, as a data erasing unit. A plurality of bit lines and a plurality of word lines are provided in the memory cell array 10. Each memory cell is associated with a bit line and a word line, for example. A detailed configuration of the memory cell array 10 will be described later.

The command register 11 stores a command CMD received by the memory device 3 from the memory controller 2. The command CMD includes, for example, a command for causing the sequencer 13 to execute a read operation, a write operation, an erase operation, and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select a block BLK, a word line, and a bit line, respectively.

The sequencer 13 controls the entire operation of the memory device 3. For example, the sequencer 13 controls the driver module 14, the row decoder module 15, the sense amplifier module 16, and the like based on the command CMD stored in the command register 11 to execute the read operation, write operation, erase operation, and the like.

The driver module 14 generates a voltage used in the read operation, write operation, erase operation, and the like. Then, the driver module 14 applies the generated voltage to a signal line corresponding to a selected word line based on, for example, the page address PAd stored in the address register 12.

The row decoder module 15 selects a corresponding block BLK in the memory cell array 10 based on the block address BAd stored in the address register 12. Then, the row decoder module 15 transfers, for example, the voltage applied to the signal line corresponding to the selected word line to the selected word line in the selected block BLK.

In the write operation, the sense amplifier module 16 applies a desired voltage to each bit line according to write data DAT received from the memory controller 2. In addition, in the read operation, the sense amplifier module 16 determines the data stored in the memory cell based on the voltage of the bit line, and transfers the determination result to the memory controller 2 as read data DAT.

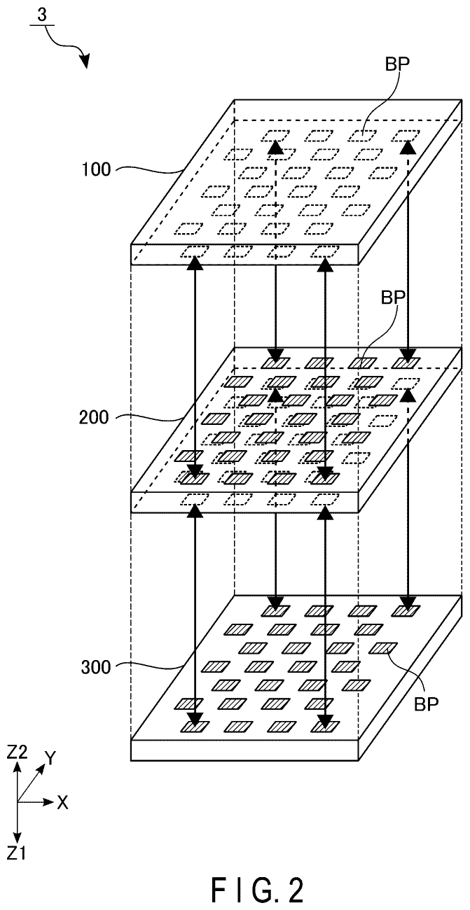

FIG. 2 is a perspective view illustrating an outline of a bonding structure of the memory device according to the first embodiment.

As illustrated in FIG. 2, the memory device 3 includes memory chips 100 and 200 and a circuit chip 300. Each of the memory chips 100 and 200 includes a structure corresponding to the memory cell array 10. The circuit chip 300 includes, for example, a structure corresponding to the command register 11, the address register 12, the sequencer 13, the driver module 14, the row decoder module 15, and the sense amplifier module 16.

In addition, each of the memory chips 100 and 200 and the circuit chip 300 includes a plurality of bonding pads BP. The memory device 3 is formed by bonding the memory chip 100 with the memory chip 200 and the memory chip 200 with the circuit chip 300 via a plurality of the bonding pads BP. In other words, the memory chip 200 is provided between the memory chip 100 and the circuit chip 300, and has a surface bonded to the memory chip 100 and a surface bonded to the circuit chip 300.

Hereinafter, the surfaces of the memory chips 100, 200 and the circuit chip 300 that are bonded (bonding surfaces) are referred to as XY surfaces. Directions orthogonal to each other on the XY plane are defined as an X direction and a Y direction. Further, a direction substantially perpendicular to the XY plane and runs from the memory chip 100 toward the circuit chip 300 is defined as a Z1 direction. The direction substantially perpendicular to the XY plane and runs from the circuit chip 300 toward the memory chip 100 is defined as a Z2 direction. In a case where the Z1 direction and the Z2 direction are not distinguished, the direction is referred to as a Z direction.

### 1.1.3 Memory Cell Array

Next, a configuration of the memory cell array included in the memory device according to the embodiment will be described.

### <Circuit Configuration>

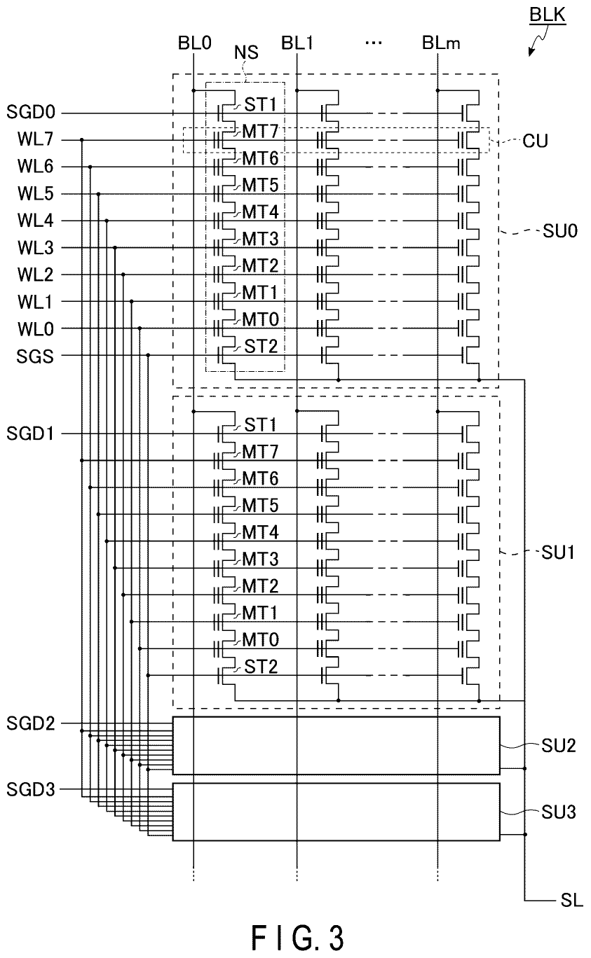

FIG. 3 is a circuit diagram illustrating an example of a circuit configuration of the memory cell array included in the memory device according to the first embodiment. FIG. 3 illustrates one block BLK among the plurality of blocks BLK included in the memory cell array 10. As illustrated in FIG. 3, the block BLK includes, for example, four string units SU0 to SU3.

Each string unit SU includes a plurality of NAND strings NS associated with bit lines BL0 to BLm (m is an integer equal to or greater than one). The number of the bit lines BL may be one. Each NAND string NS includes, for example, memory cell transistors MT0 to MT7 and select transistors ST1 and ST2. Each memory cell transistor MT includes a control gate and a charge storage unit, and stores data in a non-volatile manner. Each of the select transistors ST1 and ST2 is used to select the string unit SU during various operations.

In each NAND string NS, the memory cell transistors MT0 to MT7 are connected in series. A drain of the select transistor ST1 is connected to an associated bit line BL. A source of the select transistor ST1 is connected to one end of the memory cell transistors MT0 to MT7 connected in series. A drain of the select transistor ST2 is connected to the other end of the memory cell transistors MT0 to MT7 connected in series. A source of the select transistor ST2 is connected to the source line SL.

In a same block BLK, the control gates of the memory cell transistors MT0 to MT7 are connected to the word lines WL0 to WL7, respectively. The gates of the select transistor ST1 in the string units SU0 to SU3 are connected to select gate lines SGDO to SGD3, respectively. The gates of the plurality of select transistors ST2 are connected to the select gate line SGS.

Different column addresses are allocated to the bit lines BL0 to BLm. Each bit line BL is shared by the NAND strings NS to which the same column address is allocated among the plurality of blocks BLK. Each of the word lines WL0 to WL7 is provided for each block BLK. The source line SL is shared among the plurality of blocks BLK, for example.

A set of the plurality of memory cell transistors MT connected to the common word line WL in a string unit SU is referred to as, for example, a cell unit CU. For example, the storage capacity of the cell unit CU including the memory cell transistor MT each storing one-bit data is defined as “one-page data”. The cell unit CU may have a storage capacity of two-page data or more according to the number of bits of data stored in the memory cell transistor MT.

Note that the circuit configuration of the memory cell array 10 included in the memory device 3 according to the first embodiment is not limited to the configuration described above. For example, the number of string units SU included in each block BLK can be designed to an any number. The number of the memory cell transistors MT and the select transistors ST1 and ST2 included in each NAND string NS can be designed to any number.

### <Planar Layout>

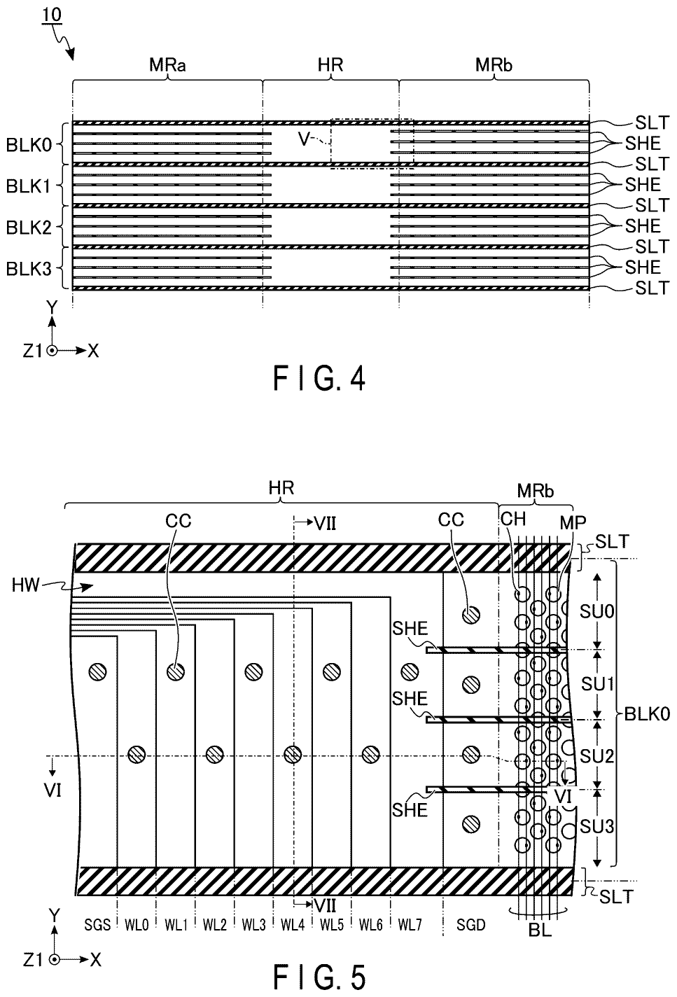

FIG. 4 is a plan view illustrating an example of a planar layout of the memory cell array included in the memory device according to the first embodiment. FIG. 4 illustrates four blocks BLK0 to BLK3 of the plurality of blocks BLK included in the memory cell array 10.

As illustrated in FIG. 4, the memory cell array includes a stacked wiring structure. The stacked wiring structure is a structure in which stacked wirings (the word lines WL0 to WL7 and the select gate lines SGD and SGS) are stacked in the Z direction. The stacked wiring structure has memory regions MRa and MRb and a hookup region HR arranged in the X direction. The memory regions MRa and MRb are regions in which the memory cell transistor MT is provided. The hookup region HR is a region provided with a contact that electrically connects the stacked wiring and the row decoder module 15. The hookup region HR is disposed between the memory region MRa and the memory region MRb.

Each of the plurality of blocks BLK extends in the X direction so as to cross the memory region MRa, the hookup region HR, and the memory region MRb. The plurality of blocks BLK are arranged in the Y direction. The memory cell array 10 includes, for example, a plurality of members SLT and a plurality of members SHE.

Each member SLT extends in the X direction so as to cross the memory region MRa, the hookup region HR, and the memory region MRb. The plurality of members SLT are arranged in the Y direction. Each member SLT has, for example, a structure in which an insulator is embedded. Each member SLT divides the adjacent stacked wiring with the member SLT interposed therebetween. In the memory cell array 10, each of the regions divided by the member SLT corresponds to one block BLK.

The plurality of members SHE include a plurality of members SHE arranged in the Y direction in the memory region MRa and a plurality of members SHE arranged in the Y direction in the memory region MRb. Each member SHE disposed in the memory region MRa extends in the X direction so as to cross the memory region MRa. Each member SHE disposed in the memory region MRb extends in the X direction so as to cross the memory region MRb. In the example of FIG. 4, in each of the memory regions MRa and MRb, three members SHE are arranged between two members SLT adjacent in the Y direction. Each member SHE has, for example, a structure in which an insulator is embedded. Each member SHE divides the select gate line SGD among the stacked wirings adjacent to each other with the member SHE interposed therebetween. In the memory cell array 10, each of regions divided by a pair of adjacent members SLT and SHE or a pair of adjacent two members SHE corresponds to one string unit SU.

The planar layout of the memory cell array 10 may be a different layout. For example, the number of members SHE disposed between two adjacent members SLT can be designed to be any number. The number of string units SU included in each block BLK can be changed based on the number of members SHE arranged between two adjacent members SLT.

FIG. 5 is a plan view corresponding to a region V in FIG. 4 and illustrating an example of a planar layout of the memory cell array included in the memory device according to the first embodiment. In FIG. 5, a boundary portion between the hookup region HR and the memory region MRb in the block BLK0 is illustrated.

First, the planar layout of the memory cell array in the memory region MRb will be described.

As illustrated in FIG. 5, the memory cell array includes, for example, a plurality of memory pillars MP, a plurality of contacts CH, and a plurality of bit lines BL in the memory region MRb.

Each memory pillar MP functions as one NAND string NS. The plurality of memory pillars MP are arranged in 19 rows in a staggered manner, for example, in a region between two adjacent members SLT. For example, one member SHE is arranged to overlap each of the memory pillars MP of the fifth column, the memory pillars MP of the 10th column, and the memory pillars MP of the 15th column in a case of counting from the upper side in the drawing.

The plurality of bit lines BL are arranged in the X direction. Each bit line BL is arranged so as to overlap at least one memory pillar MP in each string unit SU. In the example of FIG. 5, two bit lines BL are arranged to overlap a memory pillar MP. The memory pillar MP is electrically connected to a bit line BL of the plurality of bit lines BL arranged in an overlapping manner via the contact CH. Note that a contact CH between the memory pillar MP and the bit line BL in contact with the two different select gate lines SGD (that is, disposed so as to overlap with the member SHE) can be omitted.

Note that the planar layout in the memory region MR may be a different layout. For example, the number and arrangement of the memory pillars MP and the members SHE arranged between two adjacent members SLT can be appropriately changed. The number of bit lines BL overlapping each memory pillar MP can be designed to an any number.

Next, the planar layout of the memory cell array in the hookup region HR will be described.

The memory cell array 10 includes a plurality of contacts CC in the hookup region HR. In addition, the stacked wiring has a terrace portion and a highway portion HW in the hookup region HR. The terrace portion is a portion where the stacked wiring does not overlap the stacked wiring of the upper layer in the Z1 direction. The highway portion HW is a portion aligned with the terrace portion in the Y direction.

The stacked wiring forms a staircase structure in the terrace portion. In the example of FIG. 5, steps are formed between the select gate line SGS and the word line WL0, between the word line WL0 and the word line WL1, between the word line WL6 and the word line WL7, and between the word line WL7 and the select gate line SGD.

The stacked wiring of the memory region MRa and the stacked wiring of the memory region MRb are continuously provided via the highway portion HW in the hookup region HR except for the select gate line SGD. In other words, the highway portion HW corresponds to a portion continuously connecting the memory regions MRa and MRb along the member SLT.

The contacts CC are conductors used for connection between the row decoder module 15 and the stacked wiring. The plurality of contacts CC associated with the block BLK are respectively connected to the terrace portions of the select gate lines SGS and SGD and the word lines WL0 to WL7 provided in the hookup region HR. In a case where the select gate line SGD on the memory region MRa side and the select gate line SGD on the memory region MRb side are associated with the same string unit SU, the respective select gate lines SGD on the memory regions MRa and MRb are electrically connected via, for example, an upper wiring layer (not illustrated). 1.1.4 Cross-Sectional Structure of Memory Device

A cross-sectional structure of the memory device according to the embodiment will be described.

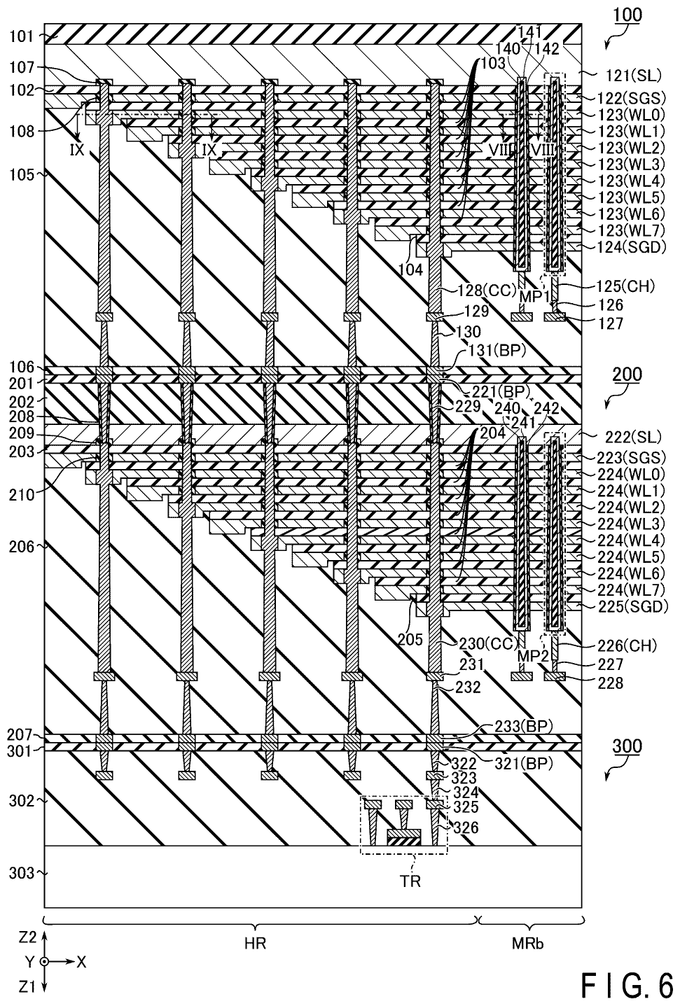

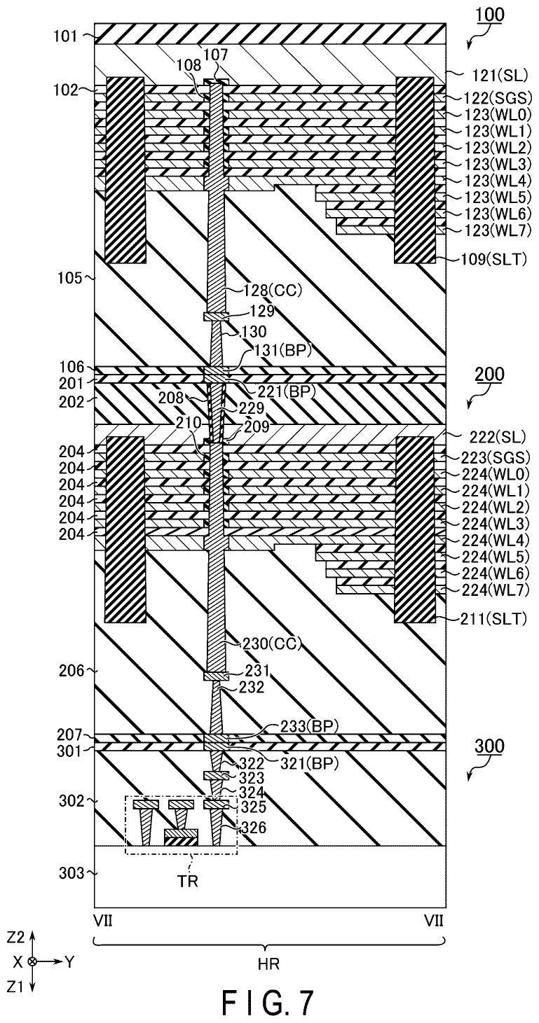

FIG. 6 is a cross-sectional view taken along a line VI-VI of FIG. 5 and illustrating an example of the cross-sectional structure of the memory device according to the first embodiment. FIG. 7 is a cross-sectional view taken along a line VII-VII of FIG. 5 and illustrating an example of the cross-sectional structure of the memory device according to the first embodiment.

First, the cross-sectional structure of the memory chip 100 will be described with reference to FIGS. 6 and 7.

The memory chip 100 includes a memory pillar MP1, insulating layers 101, 102, 103, 104, 105, and 106, insulators 107, 108, and 109, a semiconductor layer 121, wiring layers 122, 123, and 124, conductive layers 127, 129, and 131, and conductors 125, 126, 128, and 130.

The semiconductor layer 121 is provided on the upper surface of the insulating layer 101 in the Z1 direction. The semiconductor layer 121 is formed in, for example, a plate shape extending along the XY plane. The semiconductor layer 121 includes, for example, polysilicon and is used as the source line SL.

The insulating layer 102 and the wiring layer 122 are stacked one by one on the upper surface of the semiconductor layer 121 in the Z1 direction. The wiring layer 122 is formed in, for example, a plate shape extending along the XY plane. The wiring layer 122 contains, for example, tungsten and is used as the select gate line SGS.

On the upper surface of the wiring layer 122 in the Z1 direction, eight insulating layers 103 and eight wiring layers 123 are stacked one by one. Each of the eight wiring layers 123 is formed in, for example, a plate shape extending along the XY plane. The eight wiring layers 123 include tungsten, for example, and are used as the word lines WL0 to WL7 in order from the side closer to the semiconductor layer 121.

On the upper surface of the uppermost wiring layer 123 in the Z1 direction, the insulating layer 104 and the wiring layer 124 are stacked one by one. The wiring layer 124 is formed in, for example, a plate shape extending along the XY plane. The wiring layer 124 includes, for example, tungsten and is used as the select gate line SGD.

The wiring layers 122, 123, and 124 as described above constitute the stacked wiring. Each of the wiring layers 122, 123, and 124 has a terrace portion that does not overlap the upper wiring layer in the Z1 direction in the hookup region HR. The film thickness of the terrace portion of each of the wiring layers 122, 123, and 124 is larger than the film thickness of the other portion of each of the wiring layers 122, 123, and 124, for example.

The conductive layer 127 is provided above the wiring layer 124 in the Z1 direction. The conductive layer 127 is formed in, for example, a line shape extending in the Y direction. The conductive layer 127 includes, for example, copper and is used as the bit line BL.

The insulator 109 has a plate-like portion extending along the XZ plane. The insulator 109 divides the insulating layers 102 to 104 and the wiring layers 122 to 124 and is used as the member SLT.

The memory pillar MP1 extends in the Z direction and penetrates the stacked wiring structure of the memory chip 100 in the memory region MRb. The memory pillar MP1 includes, for example, a core film 140, a semiconductor film 141, and stacked films 142. The core film 140 is an insulator extending in the Z direction. One end of the core film 140 reaches below the wiring layer 122 in the Z1 direction. The other end of the core film 140 reaches above the wiring layer 124 in the Z1 direction. The semiconductor film 141 covers the core film 140. One end of the semiconductor film 141 is in contact with the semiconductor layer 121. The stacked films 142 cover the side surface of the semiconductor film 141.

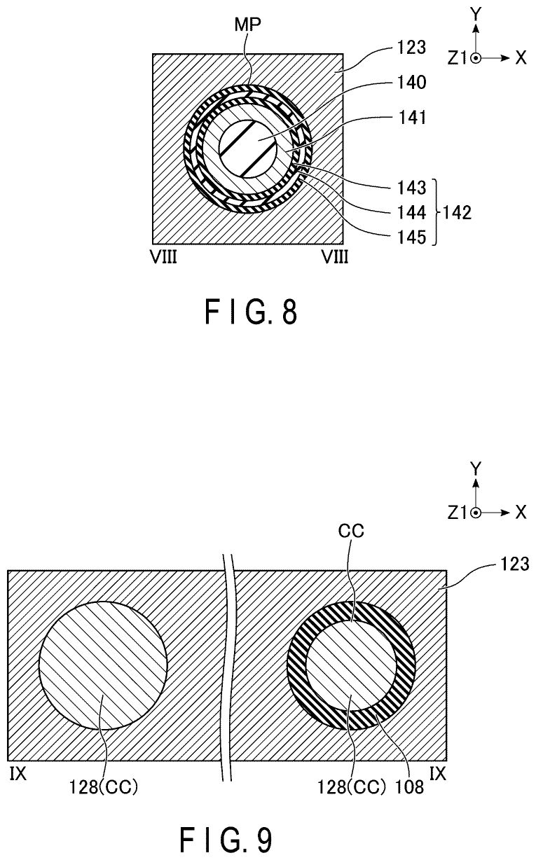

FIG. 8 is a cross-sectional view taken along a line VIII-VIII of FIG. 6 and illustrating an example of the cross-sectional structure of the memory pillar included in the memory device according to the first embodiment. FIG. 8 illustrates a cross section parallel to the XY plane and including the memory pillar MP1 and the wiring layer 123. As illustrated in FIG. 8, the stacked films 142 include, for example, a tunnel insulating film 143, a charge storage film 144, and a block insulating film 145.

The core film 140 is provided, for example, in a central portion of the memory pillar MP1. The semiconductor film 141 surrounds the side surface of the core film 140. The tunnel insulating film 143 surrounds the side surface of the semiconductor film 141. The charge storage film 144 surrounds the side surface of the tunnel insulating film 143. The block insulating film 145 surrounds the side surface of the charge storage film 144. The wiring layer 123 surrounds the side surface of the block insulating film 145. The semiconductor film 141 is used as a channel (current path) of the memory cell transistors MT0 to MT7 and the select transistors ST1 and ST2. Each of the tunnel insulating film 143 and the block insulating film 145 includes, for example, silicon oxide. The charge storage film 144 includes, for example, silicon nitride. With this configuration, a portion where the memory pillar MP intersects the wiring layer 123 functions as the memory cell transistor MT. Similarly, a portion where the memory pillar MP1 intersects the wiring layer 124 functions as the select transistor ST1. A portion where the memory pillar MP1 intersects the wiring layer 122 functions as the select transistor ST2. Therefore, the memory pillar MP1 functions as a NAND string NS.

The cross-sectional structure of the memory chip 100 will be described again with reference to FIGS. 6 and 7.

The conductor 125 is provided on the upper surface of the memory pillar MP1 in the Z1 direction of the semiconductor film 141. The conductor 125 has, for example, a columnar shape and is used as the contact CH. The conductor 125 is provided on the upper surface of the conductor 126 in the Z1 direction. The conductor 126 has a columnar shape. The conductor 126 is connected to a corresponding conductive layer 127.

The conductor 128 extends in the Z direction at the terrace portion of the hookup region HR and penetrates the stacked wiring structure. One end of the conductor 128 reaches the semiconductor layer 121, for example. The other end of the conductor 128 reaches, for example, above the wiring layer 124 in the Z1 direction. The conductor 128 has a columnar shape and is used as the contact CC.

The insulator 107 is provided between the conductor 128 and the semiconductor layer 121. The insulator 107 includes, for example, silicon oxide. With this configuration, the conductor 128 is electrically insulated from the semiconductor layer 121.

FIG. 9 is a cross-sectional view taken along a line IX-IX in FIG. 6 and illustrating an example of a cross-sectional structure of the contact included in the memory device according to the first embodiment. FIG. 9 illustrates a cross section parallel to the XY plane and including the contact CC and the wiring layer 123.

As illustrated in FIG. 9, the insulator 108 is provided between the conductor 128 and a wiring layer disposed lower than the corresponding wiring layer in the Z1 direction. The insulator 108 includes, for example, silicon oxide. With this configuration, the conductor 128 is electrically insulated from the wiring layers below the corresponding wiring layer in the Z1 direction among the wiring layers 122, 123, and 124.

The conductor 128 and the corresponding wiring layer are electrically connected to each other by being in contact with each other at the thickened portion of the terrace portion. A diameter of a contact portion of the conductor 128 with the corresponding wiring layer is larger than other portions of the conductor 128. The diameter of the contact portion of the conductor 128 with the corresponding wiring layer is, for example, equal to the diameter of the insulator 108.

The cross-sectional structure of the memory chip 100 will be described again with reference to FIGS. 6 and 7.

The conductive layer 129 having a linear shape is provided on an upper surface of the conductor 128 in the Z1 direction. The conductor 130 having a columnar shape is provided on the upper surface of the conductive layer 129 in the Z1 direction.

The stacked wiring structure of the memory chip 100, the memory pillars MP1, the conductors 125, 126, 128, and 130, and the conductive layers 127 and 129 are covered with, for example, the insulating layer 105. The insulating layer 106 is provided on the upper surface of the insulating layer 105 in the Z1 direction. The insulating layer 106 is in contact with the insulating layer 201 included in the memory chip 200. The boundary between the insulating layer 106 and the insulating layer 201 corresponds to the bonding surface between the memory chip 100 and the memory chip 200.

For example, the conductive layer 131 having a rectangular shape is provided on the upper surface of the conductor 130 in the Z1 direction. The conductive layer 131 is used as the bonding pad BP of the memory chip 100. The conductive layer 131 is provided in the same layer as the insulating layer 106 and is in contact with a conductive layer 221 included in the memory chip 200.

Next, the cross-sectional structure of the memory chip 200 will be described with reference to FIGS. 6 and 7.

The memory chip 200 includes a memory pillar MP2, insulating layers 201, 202, 203, 204, 205, 206, and 207, insulators 208, 209, 210, and 211, a semiconductor layer 222, wiring layers 223, 224, and 225, conductive layers 228, 231, and 233, and conductors 226, 227, 229, 230, and 232.

The conductive layer 221 is provided in the same layer as the insulating layer 201. The conductive layer 221 is used as the bonding pad BP of the memory chip 100 on a bonding surface with the memory chip 200.

On the upper surface of the insulating layer 201 in the Z1 direction, the insulating layer 202 and the semiconductor layer 222 are stacked one by one. The semiconductor layer 222 is formed in, for example, a plate shape extending along the XY plane. The semiconductor layer 222 includes, for example, polysilicon and is used as the source line SL.

A stacked wiring structure of the memory chip 200 is provided on the upper surface of the semiconductor layer 222 in the Z1 direction. The stacked wiring structure of the memory chip 200 includes, for example, the insulating layers 203, 204, and 205, and the wiring layers 223, 224, and 225. The stacked wiring structure of the memory chip 200 is equivalent to the stacked wiring structure of the memory chip 100. In other words, the insulating layers 203, 204, and 205 and the wiring layers 223, 224, and 225 have the same configurations as the insulating layers 102, 103, and 104 and the wiring layers 122, 123, and 124, respectively.

The conductive layer 228 is provided above the wiring layer 225 in the Z1 direction. The conductive layer 228 is formed in, for example, a line shape extending in the Y direction. The conductive layer 228 includes, for example, copper and is used as the bit line BL.

The insulator 211 has a plate-like portion extending along the XZ plane. The insulator 211 divides the insulating layers 203 to 205 and the wiring layers 223 to 225 and is used as the member SLT.

The memory pillar MP2 extends in the Z direction and penetrates the stacked wiring structure of the memory chip 200 in the memory region MRb. The memory pillar MP2 includes, for example, a core film 240, a semiconductor film 241, and stacked films 242. The structure of the memory pillar MP2 is equivalent to the structure of the memory pillar MP1. In other words, the core film 240, the semiconductor film 241, and the stacked films 242 have the same configurations as those of the core film 140, the semiconductor film 141, and the stacked films 142, respectively.

The conductor 226 is provided on the upper surface of the semiconductor film 241 in the memory pillar MP2 in the Z1 direction. The conductor 226 has, for example, a columnar shape and is used as the contact CH. The conductor 226 is provided on the upper surface of the conductor 227 in the Z1 direction. The conductor 227 has a columnar shape. The conductor 227 is connected to the corresponding conductive layer 228.

The conductor 230 extends in the Z direction at the terrace portion of the hookup region HR and penetrates the stacked wiring structure. One end of the conductor 230 reaches the semiconductor layer 222, for example. The other end of the conductor 230 reaches, for example, above the wiring layer 235 in the Z1 direction. The conductor 230 has a columnar shape and is used as the contact CC.

The insulator 209 is provided between the conductor 230 and the semiconductor layer 222. The insulator 208 includes, for example, silicon oxide. With this configuration, the conductor 230 is electrically insulated from the semiconductor layer 222.

The insulator 210 is provided between the conductor 230 and the wiring layers disposed lower than the corresponding wiring layer in the Z1 direction. The insulator 210 includes, for example, silicon oxide. With this configuration, the conductor 230 is electrically insulated from the wiring layers below the corresponding wiring layer in the Z1 direction among the wiring layers 223, 224, and 235.

The conductor 230 and the corresponding wiring layer are electrically connected to each other by being in contact with each other at the thickened portion of the terrace portion. A diameter of a contact portion of the conductor 230 with the corresponding wiring layer is larger than other portions of the conductor 230. The diameter of the contact portion of the conductor 230 with the corresponding wiring layer is, for example, equal to the diameter of the insulator 210.

The conductor 229 is provided on the upper surface of the conductive layer 221 in the Z1 direction and extends in the Z direction. An upper end of the conductor 229 in the Z1 direction is in contact with the other end of the conductor 230. The insulator 208 is provided on a side surface of the conductor 229. Therefore, the conductor 229 is electrically insulated from the semiconductor layer 222 and electrically connects the conductor 230 and the conductive layer 221.

The conductive layer 231 having a linear shape is provided on an upper surface of the conductor 230 in the Z1 direction. The conductor 232 having a columnar shape is provided on the upper surface of the conductive layer 231 in the Z1 direction.

The stacked wiring structure of the memory chip 200, the memory pillars MP2, the conductors 226, 227, 230, and 232, and the conductive layers 228 and 231 are covered with, for example, the insulating layer 206. The insulating layer 207 is provided on the upper surface of the insulating layer 206 in the Z1 direction. The insulating layer 207 is in contact with the insulating layer 301 included in the circuit chip 300. The boundary between the insulating layer 207 and the insulating layer 301 corresponds to the bonding surface between the memory chip 200 and the circuit chip 300.

For example, a conductive layer 233 having a rectangular shape is provided on the upper surface of the conductor 232 in the Z1 direction. The conductive layer 233 is used as a bonding pad BP of the memory chip 200 on a bonding surface with the circuit chip 300. The conductive layer 233 is provided in the same layer as the insulating layer 207 and is in contact with the conductive layer 321 included in the circuit chip 300.

Next, the cross-sectional structure of the circuit chip 300 will be described with reference to FIGS. 6 and 7.

The circuit chip 300 includes insulating layers 301 and 302, a substrate 303, conductive layers 321, 323, and 325, conductors 322, 324, and 326, and a transistor TR.

The conductive layer 321 is provided in the same layer as the insulating layer 301. The conductive layer 321 is used as a bonding pad BP of the circuit chip 300 on a bonding surface with the memory chip 200.

On the upper surface of the insulating layer 301 in the Z1 direction, the insulating layer 302 and the substrate 303 are stacked one by one. The substrate 303 is, for example, a silicon substrate. Various circuits including the transistor TR are formed on the substrate 303. The transistor TR illustrated in FIGS. 6 and 7 is a circuit in the row decoder module 15.

In the insulating layer 301, the conductor 322 having a columnar shape is provided on the upper surface of the conductive layer 321 in the Z1 direction. The conductive layer 323 having a linear shape is provided on an upper surface of the conductor 322 in the Z1 direction. The conductor 324 having a columnar shape is provided on the upper surface of the conductive layer 323 in the Z1 direction. The conductive layer 325 is provided on the upper surface of the conductor 324 in the Z1 direction. The conductor 326 having a columnar shape is provided on the upper surface of the conductive layer 325 in the Z1 direction. An upper surface of the conductor 326 in the Z1 direction is connected to the transistor TR on the substrate 303.

With the above configuration, the specific word line WL of each of the memory chips 100 and 200 is electrically connected via the conductors 128 and 230, and is commonly connected to the transistor TR in the circuit chip 300.

In the examples of FIGS. 6 and 7, the electrical connection relationship between the word line WL of each of the memory chips 100 and 200 and the circuit chip 300 is illustrated, but the connection relationship between the memory chips 100 and 200 and the circuit chip 300 is not limited thereto. For example, although not illustrated in FIGS. 6 and 7, the bit lines BL, the source line SL, and the like of each of the memory chips 100 and 200 are also electrically connected to the circuit chip 300.

### 1.2 Manufacturing Method

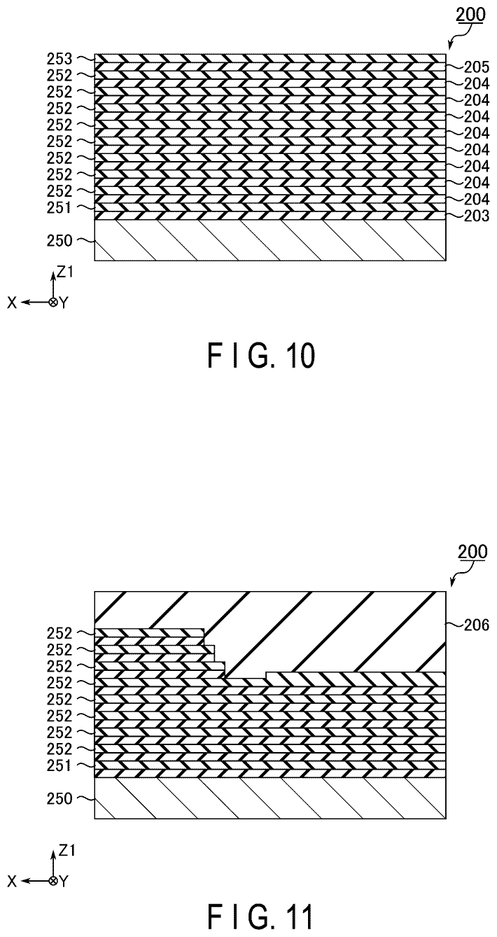

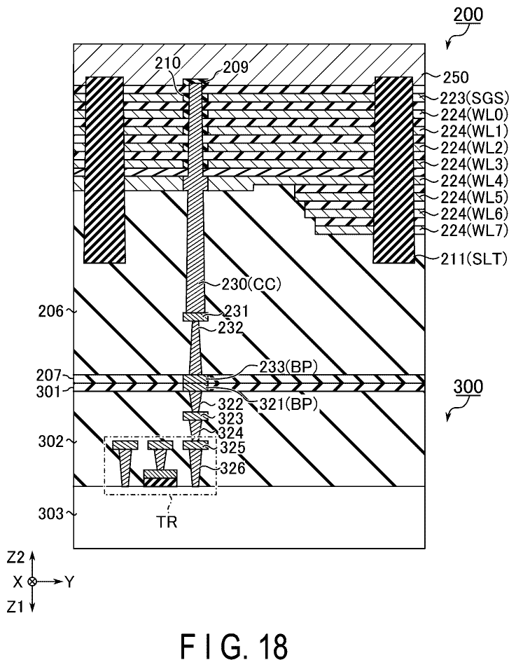

FIGS. 10 to 20 are cross-sectional views illustrating an example of a cross-sectional structure in a process of manufacturing the memory device according to the first embodiment. FIGS. 10 to 17 correspond to the memory chip 200 in the cross section illustrated in FIG. 7. FIGS. 18 to 20 correspond to the cross section illustrated in FIG. 7.

First, the memory chips 100 and 200 and the circuit chip 300 are individually formed. Focusing on the process of forming the memory chip 200, as illustrated in FIG. 10, the insulating layer 203 and the sacrificial member 251 are stacked in this order on the upper surface of the substrate 250 in the Z1 direction. On the upper surface of the sacrificial member 251 in the Z1 direction, eight insulating layers 204 and eight sacrificial members 252 are stacked one by one in this order. The insulating layer 205 and the sacrificial member 253 are stacked in this order on the upper surface of the uppermost sacrificial member 252 in the Z1 direction. The insulating layers 203, 204, and 205 include, for example, silicon oxide. The sacrificial members 251, 252, and 253 include, for example, silicon nitride. With this configuration, a stacked structure corresponding to the stacked wiring structure is provided.

Subsequently, as illustrated in FIG. 11, a staircase structure is formed in a region corresponding to the hookup region HR of the stacked structure. In the formation of the staircase structure, the sacrificial member 253 and the insulating layers 204 are removed in the hookup region HR. Then, after thickening the film thickness of each of the sacrificial members 251, 252, and 253 forming the staircase structure in a part of the terrace portion, the staircase structure is covered with the insulating layer 206. The thickened portion of a certain sacrificial member is formed so as not to be in contact with the terrace portion of the sacrificial member on the upper layer in the Z1 direction. In other words, there is a portion that is not thickened between the thickened portion of the certain sacrificial member and the portion of the sacrificial member that is not in the terrace portion.

Thereafter, although not illustrated, a structure corresponding to the memory pillar MP2 is formed. For example, in the stacked structure, a hole is formed in a region where the memory pillar MP2 is to be formed. The hole penetrates the insulating layer 206 and the stacked structure and reaches the substrate 250. Then, the stacked films 242, the semiconductor film 241, and the core film 240 are formed in this order in the hole, whereby the hole is embedded. At this point, the end of the semiconductor film 241 on the substrate 250 side is covered with the stacked films 242.

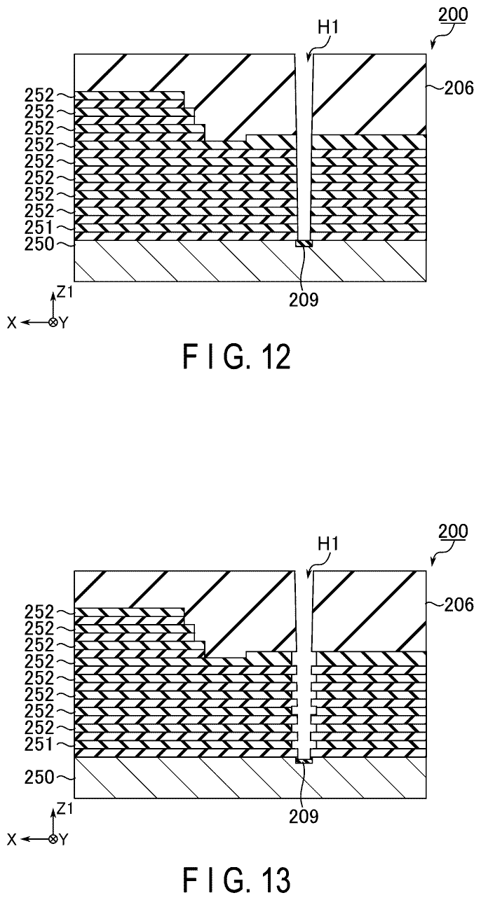

Subsequently, as illustrated in FIG. 12, a hole H1 is formed in a region where the contact CC is to be formed. The hole H1 penetrates the insulating layer 206 and the stacked structure and reaches the substrate 250. The hole H1 penetrates the terrace portion thickened in the stacked structure. As a result, the substrate 250 is exposed at the bottom of the hole H1. Then, the insulator 209 is formed by oxidizing the portion of the substrate 250 exposed to the bottom portion of the hole H1.

Subsequently, as illustrated in FIG. 13, the sacrificial members 251 and 252 exposed in the hole H1 are partially removed by, for example, wet etching. As a result, recesses are formed in portions of the hole H1 where the sacrificial members 251 and 252 are provided.

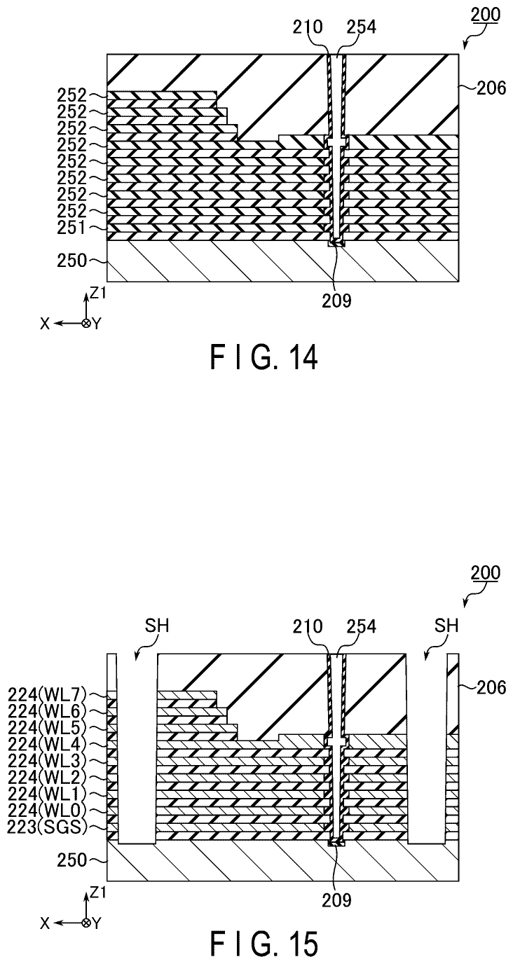

Subsequently, as illustrated in FIG. 14, the hole H1 is embedded by forming the insulator 210 and the sacrificial member 254 in this order in the hole H1. In the formation of the insulator 210, the recesses (small recesses) formed in the non-thickened portion of the sacrificial member in the hole H1 are embedded by the insulator 210. On the other hand, the recess (large recess) formed in the thick film portion of the sacrificial member in the hole H1 is not fully embedded by the insulator 210. In other words, in the formation of the insulator 210, a large recess in the hole H1 is maintained.

Subsequently, as illustrated in FIG. 15, slits SH are formed in regions where the members SLT are to be formed. The slits SH penetrate the insulating layer 206 and the stacked structure and reach the substrate 250. A replacement process of the stacked structure is executed through the slits SH. In the replacement process of the stacked structure, the sacrificial members 251, 252, and 253 are selectively removed through the slits SH by wet etching with hot phosphoric acid or the like. Then, the conductor is embedded in the space from which the sacrificial members 251, 252, and 253 are removed through the slits SH. Thereafter, the conductor formed inside the slits SH is removed by etch-back processing. As a result, the conductor formed inside the slits SH is separated into a plurality of conductive layers. As described above, the wiring layer 223 functioning as the select gate line SGS, the plurality of wiring layers 224 each functioning as the word line WL, and the wiring layer 225 functioning as the select gate line SGD are formed. After the replacement process in the stacked structure, the slits SH are embedded by the insulator 211, whereby the member SLT is formed.

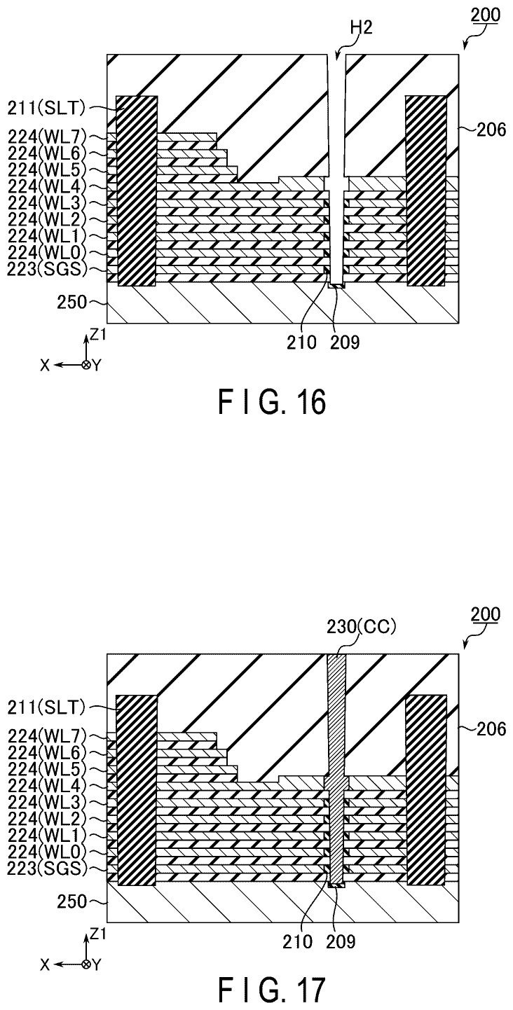

Subsequently, as illustrated in FIG. 16, the sacrificial member 254 is removed to form a hole H2. Then, the insulator 210 is partially removed through the hole H2. In a case where the insulator 210 is removed, the portions of the insulator 210 that fill the small recesses in the hole H2 remain. On the other hand, the portion of the insulator 210 provided in the large recess in the hole H2 and the remaining portion of the insulator 210 are removed. As a result, among the wiring layers 223 and 224, the thickened wiring layer is exposed in the hole H2, but the wiring layers which are not thickened are not exposed due to the remaining insulator 210.

Subsequently, as illustrated in FIG. 17, the conductor 230 is embedded in the hole H2 to form the contact CC. The conductor 230 is selectively and electrically connected to the thickened wiring layer in the hole H2. On the other hand, the conductor 230 is electrically insulated by the insulator 210 with respect to the wiring layer which is not thickened in the hole H2. In addition, the conductor 230 is electrically insulated from the substrate 250 by the insulator 209 in the hole H2. Thereafter, the conductive layer 231, the conductor 232, and the conductive layer 233 of the memory chip 200 are formed.

Subsequently, as illustrated in FIG. 18, the separately formed circuit chip 300 and the memory chip 200 are bonded together. At the time of bonding, the conductive layer 233 of the memory chip 200 and the conductive layer 321 of the circuit chip 300 are electrically connected.

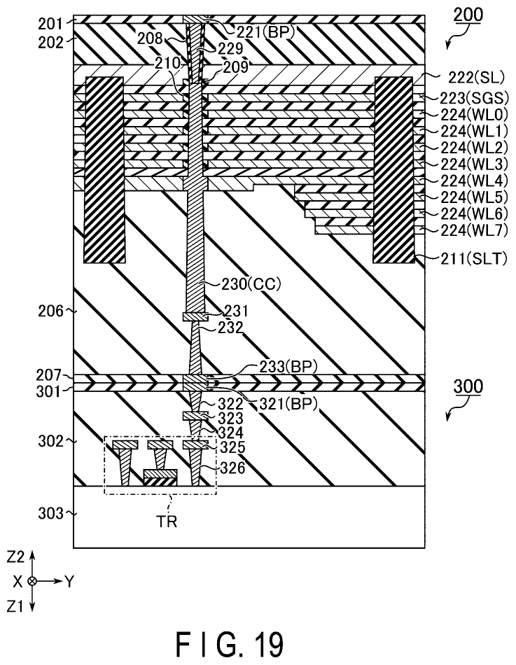

Subsequently, as illustrated in FIG. 19, the remaining portion of the memory chip 200 is formed. Specifically, for example, by first removing the substrate 250, the end of the stacked films 242 of the memory pillar MP2 is exposed. Then, the semiconductor film 241 is exposed by removing the exposed end of the stacked films 242. Next, the semiconductor layer 222 functioning as the source line SL is formed. As a result, the semiconductor layer 222 is in contact with the semiconductor film 241. Thereafter, the upper configuration of the semiconductor layer 222 in the Z2 direction is formed.

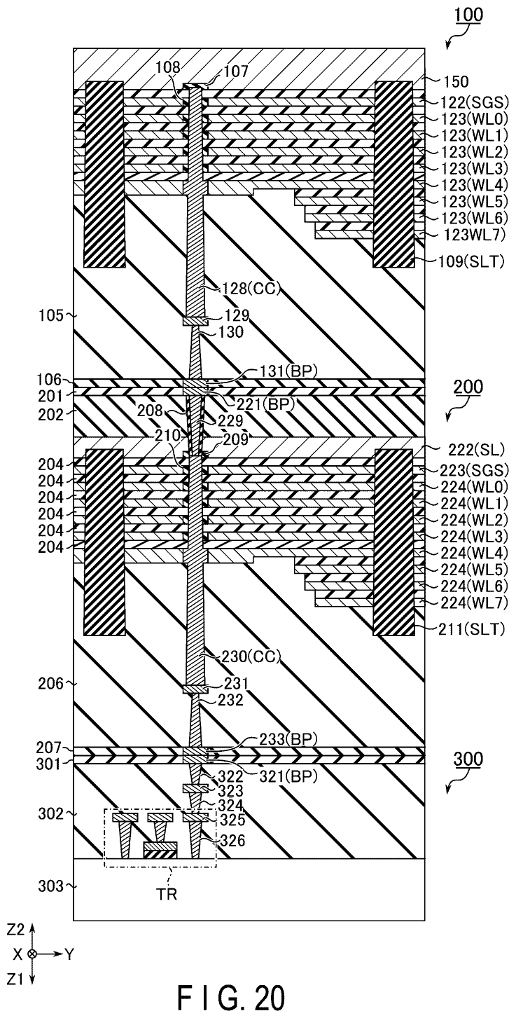

Subsequently, as illustrated in FIG. 20, the separately formed memory chip 100 and the memory chip 200 are bonded together. At the time of bonding, the conductive layer 221 of the memory chip 200 and the conductive layer 131 of the memory chip 100 are electrically connected.

Thereafter, the remaining portion of the memory chip 100 is formed. As described above, the memory device 3 is formed.

### 1.3 Effects According to First Embodiment

According to the first embodiment, the conductor 230 extends in the Z direction so as to cross the wiring layers 223, 224, and 225 and reaches the semiconductor layer 222. The conductor 230 is in contact with one of the wiring layers 223, 224, and 225, and is electrically insulated from the wiring layers 223, 224, and 225 and the semiconductor layer 222 excluding the contacting layer. The conductor 230 electrically connects the substrate 303 and one of the wiring layers 122, 123, and 124. As a result, the word line WL provided in the memory chip 100 and the word line WL provided in the memory chip 200 can be electrically connected via the conductor 230. Therefore, the staircase structure provided in the memory chip 100 and the staircase structure provided in the memory chip 200 can be arranged at positions overlapping each other as viewed in the Z direction. Therefore, the degree of integration can be improved.

In addition, the conductor 128 extends in the Z direction so as to cross the wiring layers 122, 123, and 124 and reaches the semiconductor layer 121. The conductor 128 is in contact with one of the wiring layers 122, 123, and 124, and is electrically insulated from the wiring layers 122, 123, and 124 and the semiconductor layer 121 excluding the contacting layer. The conductor 128 electrically connects one of the wiring layers 122, 123, and 124 and the conductor 230. As described above, by making the memory chips 100 and 200 have the same structure, the memory chips 100 and 200 can be manufactured in the same process up to the process of bonding the memory chips. Therefore, the manufacturing cost can be reduced as compared with a case where the memory chips 100 and 200 are manufactured in different processes.

In addition, each of the stacked wirings provided in each of the memory chips 100 and 200 has a terrace portion that does not overlap the wiring layers on the substrate 303 side as viewed in the Z direction. The conductor 230 is in contact with one of the wiring layers 223, 224, and 225 in the terrace portion. The conductor 128 is in contact with one of the wiring layers 122, 123, and 124 in the terrace portion. The film thickness of the wiring layer at the portions in contact with the conductors 230 and 128 are larger than the film thickness of the other portions. Accordingly, in a case where the staircase structure is provided in the hookup region HR, the conductors 230 and 128 penetrating the staircase structures can be formed.

### 1.4 Modification of First Embodiment

Various modifications can be applied to the first embodiment.

According to the first embodiment, the case where the contact CC penetrates the stacked wiring structure to connect the word line WL of the memory chip 100 and the word line WL of the memory chip 200 has been described, but the present invention is not limited thereto. For example, the word line WL of the memory chip 100 and the word line WL of the memory chip 200 may be connected via a contact that is different from the contact CC that does not penetrate the stacked wiring structure. Hereinafter, a configuration different from that of the first embodiment will be mainly described. Description of configurations equivalent to those of the first embodiment will be omitted as appropriate.

### 1.4.1 Planar Layout of Memory Cell Array

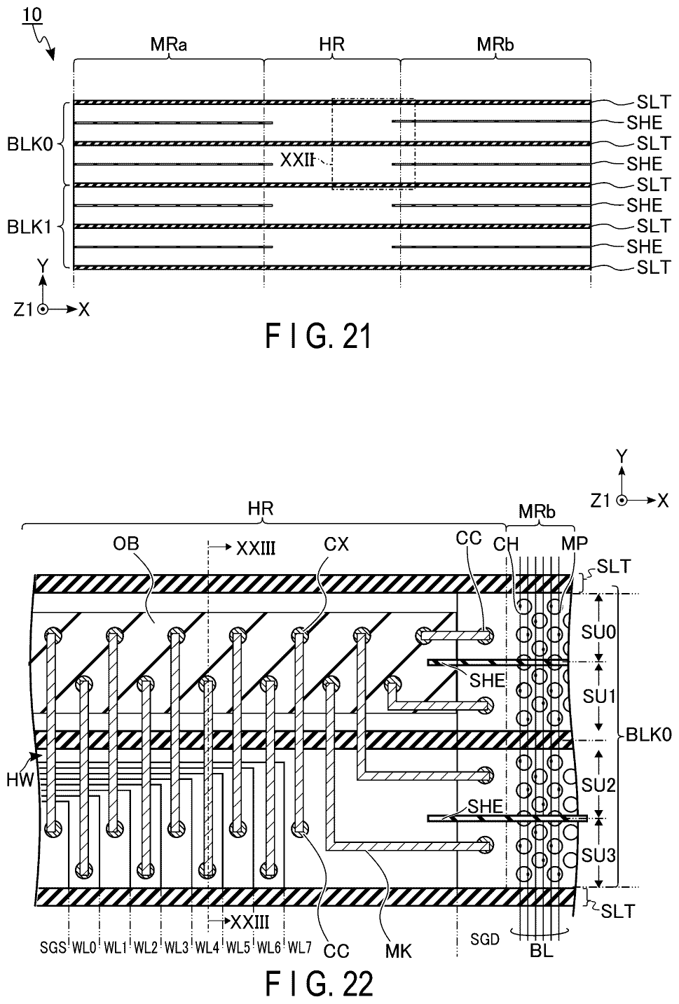

FIG. 21 is a plan view illustrating an example of a planar layout of a memory cell array included in a memory device according to a modification of the first embodiment. FIG. 21 corresponds to FIG. 4 in the first embodiment. In FIG. 21, two blocks BLK0 and BLK1 among the plurality of blocks BLK included in the memory cell array 10 are illustrated.

As illustrated in FIG. 21, in the memory cell array 10, a region divided by three continuously adjacent members SLT corresponds to one block BLK.

In the example of FIG. 21, in each of the memory regions MRa and MRb, one member SHE is arranged between two members SLT adjacent in the Y direction. Each of the regions divided by a pair of adjacent members SLT and SHE or a pair of adjacent two members SHE corresponds to one string unit SU. More specifically, a region divided by the first member SLT among the three members SLT adjacent in succession and a member SHE provided between the first and second members SLT, and a region divided by the second member SLT and the member SHE provided between the first and second members SLT respectively correspond to the string units SU0 and SU1 in one block BLK. A region divided by the second member SLT and a member SHE provided the second and third members SLT, and a region divided by the third member SLT and the member SHE provided between the second and third members SLT respectively correspond to the string units SU2 and SU3 in one block BLK.

In the example of FIG. 21, a case where the stacked wiring structure corresponding to one block BLK is divided by the second of three members SLT adjacent to each other in succession is illustrated. In this case, the two divided stacked wiring structures are electrically connected by wiring (not illustrated). In addition, the present invention is not limited to the above example, and the second of the three members SLT adjacent to each other in succession may have an intermittent structure in the X direction so that the stacked wiring structure corresponding to one block BLK is not completely divided.

FIG. 22 is a plan view corresponding to a region XXII in FIG. 21 and illustrating an example of the planar layout of the memory cell array included in the memory device according to the modification of the first embodiment. FIG. 22 corresponds to FIG. 5 in the first embodiment.

First, the planar layout of the memory cell array 10 in the memory region MRb will be described.

As illustrated in FIG. 22, the memory cell array 10 includes, for example, a plurality of memory pillars MP, a plurality of contacts CH, and a plurality of bit lines BL in the memory region MRb.

Each memory pillar MP functions as one NAND string NS. The plurality of memory pillars MP are arranged in nine rows in a staggered manner, for example, in a region between two adjacent members SLT. For example, one member SHE is arranged to overlap the memory pillars MP in the fifth column in a case of counting from the upper side in the drawing.

Next, the planar layout of the memory cell array in the hookup region HR will be described.

The memory cell array 10 includes a plurality of contacts CC and CX and a wiring MK in the hookup region HR. In addition, the stacked wiring has a terrace portion, a highway portion HW, and an insulating portion in the hookup region HR. The insulating portion is a hollowed region of the stacked wiring. An insulating member OB is embedded in the insulating portion. The terrace portion is formed in one of the regions divided by the member SLT in one block BLK. The insulating portion is formed in the other of the regions divided by the member SLT in one block BLK.

The contacts CC are conductors used for connection between the row decoder module 15 and the stacked wiring. The plurality of contacts CC associated with the block BLK are respectively connected to the terrace portions of the select gate lines SGS and SGD and the word lines WL0 to WL7 provided in the hookup region HR. In a case where the select gate line SGD on the memory region MRa side and the select gate line SGD on the memory region MRb side are associated with the same string unit SU, the select gate line SGD and the select gate line SGD are electrically connected via, for example, the contact CC and an upper wiring layers (not illustrated).

The contacts CX are conductors used for connection between the row decoder module 15 and stacked wiring in different memory chips. The plurality of contacts CX associated with the block BLK are arranged in the member OB provided in the hookup region HR.

The wiring MK is wiring for connecting the corresponding contacts CC and CX. The conductive paths led out from the stacked wiring in the different memory chips are collected into a common conductive path via the wiring MK, and then connected to the row decoder module 15.

### 1.4.2 Cross-Sectional Structure of Memory Device

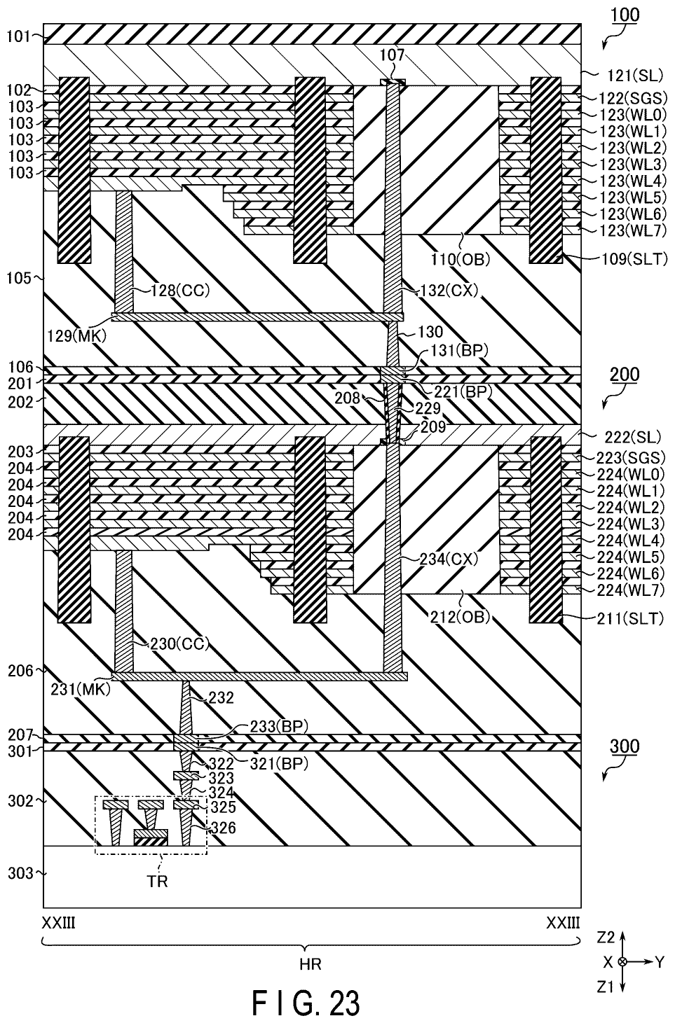

FIG. 23 is a cross-sectional view taken along a line XXIII-XXIII of FIG. 22 and illustrating an example of the cross-sectional structure of the memory device according to the modification of the first embodiment. FIG. 23 corresponds to FIG. 7 in the first embodiment.

First, a cross-sectional structure of the memory chip 200 will be described with reference to FIG. 23.

The memory chip 200 further includes an insulator 212 and a conductor 234.

The conductor 230 is provided on the upper surface, in the Z1 direction, of the corresponding wiring layer among the wiring layers 223, 224, and 225 in the terrace portion, and extends in the Z direction. The upper end of the conductor 230 in the Z1 direction reaches, for example, above the wiring layer 225 in the Z1 direction. The conductor 230 has a columnar shape and is used as the contact CC.

The insulator 212 has a portion formed in a columnar shape. The insulator 212 is provided so as to penetrate the insulating layers 203 and 204 and the wiring layers 223 and 224, and is used as a member OB.

The conductor 234 is provided so as to penetrate the insulator 212 and extends in the Z1 direction. The upper end of the conductor 234 in the Z1 direction reaches, for example, above the wiring layer 225 in the Z1 direction. The conductor 234 has a columnar shape and is used as the contact CX.

The insulator 209 is provided between the conductor 234 and the semiconductor layer 222. The insulator 209 includes, for example, silicon oxide. With this configuration, the conductor 234 is electrically insulated from the semiconductor layer 222.

The conductor 229 is provided on the upper surface of the conductive layer 221 in the Z1 direction and extends in the Z direction. An upper end of the conductor 229 in the Z1 direction is in contact with the conductor 234. The insulator 208 is provided on a side surface of the conductor 229. Therefore, the conductor 229 is electrically insulated from the semiconductor layer 222 and electrically connects the conductor 234 and the conductive layer 221.

The common conductive layer 231 is in contact with the upper surface of the conductor 230 in the Z1 direction and the corresponding upper surface of the conductor 234 in the Z1 direction. The conductive layer 231 is used as the wiring MK.

Other configurations of the memory chip 200 in the modification of the first embodiment are equivalent to those of the memory chip 200 according to the first embodiment illustrated in FIG. 7. In addition, the configuration of the memory chip 100 in the modification of the first embodiment is equivalent to that of the memory chip 200 in the modification of the first embodiment described above.

### 1.4.3 Effects According to Modification of First Embodiment

According to the modification of the first embodiment, the conductor 230 is provided on the surface of one of the wiring layers 223, 224, and 225 on the substrate 303 side and extends in the Z direction. The conductor 234 extends in the Z direction so as to cross the wiring layers 223, 224, and 225 and reaches the semiconductor layer 222. The conductor 234 is electrically connected to one of the wiring layers 223, 224, and 225 via the conductor 230, and is electrically insulated from the wiring layers 223, 224, and 225 and the semiconductor layer 222 excluding the contacting layer. The conductor 234 electrically connects the substrate 303 and one of the wiring layers 122, 123, and 124 without interposing the conductor 230 therebetween. As a result, the word line WL provided in the memory chip 100 and the word line WL provided in the memory chip 200 can be electrically connected using the conductor 234 that does not penetrate the staircase structure. Therefore, as in the first embodiment, the staircase structure provided in the memory chip 100 and the staircase structure provided in the memory chip 200 can be arranged at positions overlapping each other as viewed in the Z direction.

### 2. Second Embodiment

A memory device according to a second embodiment will be described. The second embodiment is different from the first embodiment in that a staircase structure is not formed in a stacked wiring structure. In the following description, a configuration and a manufacturing method different from those of the first embodiment will be mainly described. Description of the same configuration and manufacturing method as those of the first embodiment will be omitted as appropriate.

### 2.1 Planar Layout of Memory Cell Array

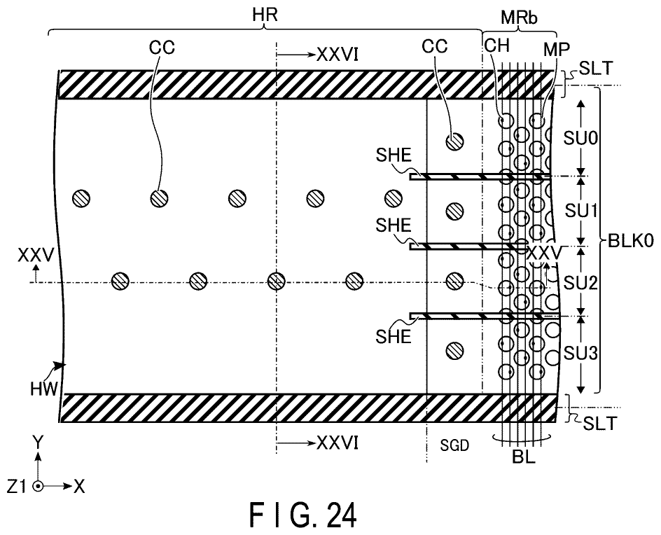

FIG. 24 is a plan view illustrating an example of a planar layout of a memory cell array included in the memory device according to the second embodiment. FIG. 24 corresponds to FIG. 5 in the first embodiment.

As illustrated in FIG. 24, a planar layout of a memory region MRb according to the second embodiment is the same as that in the first embodiment.

Each of stacked wirings of a memory cell array 10 does not have a terrace portion in a hookup region HR. Therefore, the entire stacked wiring in the hookup region HR functions as a highway portion HW. Then, a plurality of contacts CC corresponding to a select gate line SGS and word lines WL0 to WL7 are arranged in (the highway portion HW of) the hookup region HR.

### 2.2 Cross-Sectional Structure of Memory Device

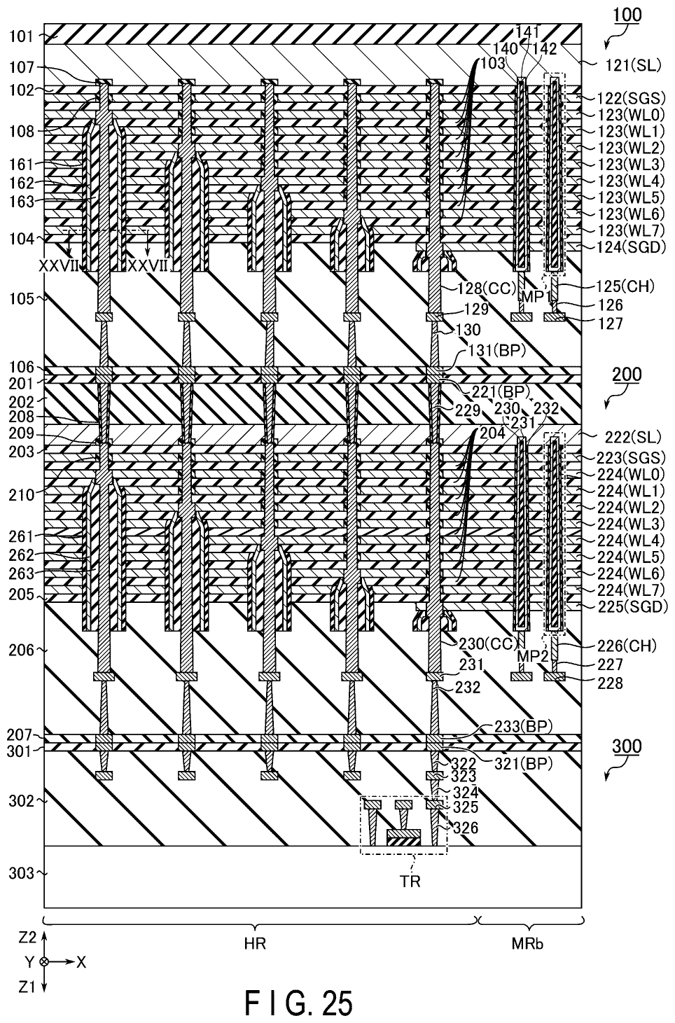

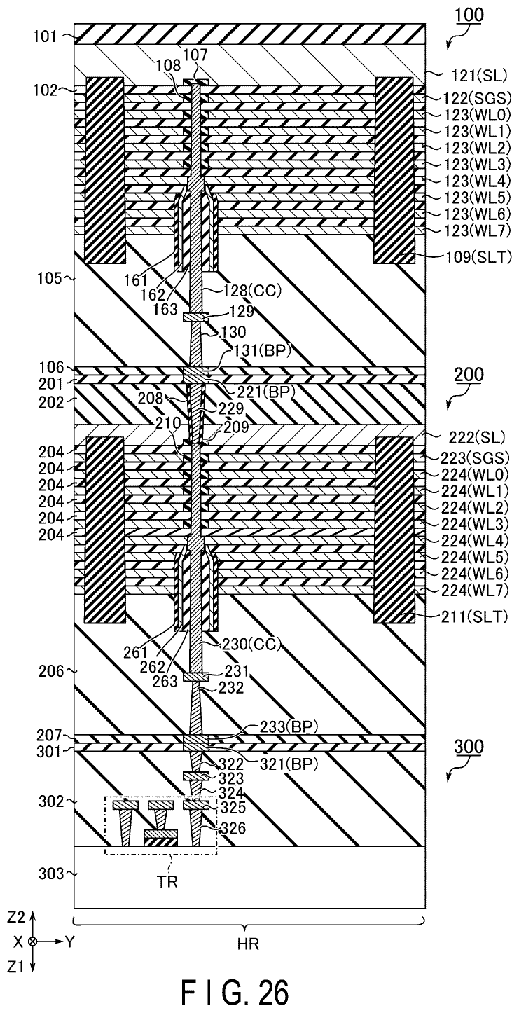

FIG. 25 is a cross-sectional view taken along a line XXV-XXV in FIG. 24 and illustrating an example of the cross-sectional structure of the memory device according to the second embodiment. FIG. 26 is a cross-sectional view taken along a line XXVI-XXVI of FIG. 24 and illustrating an example of the cross-sectional structure of the memory device according to the second embodiment. FIGS. 25 and 26 correspond to FIGS. 6 and 7 in the first embodiment, respectively.

The memory chip 100 includes a memory pillar MP1, insulating layers 101 to 106, insulators 107 to 109, 161, and 163, a semiconductor layer 121, wiring layers 122 to 124, conductive layers 127, 129, and 131, and conductors 125, 126, 128, 130, and 162.

The configurations of the insulating layer 101 and the semiconductor layer 121 are the same as those of the first embodiment.

The configuration of the stacked wiring structure is the same as that of the first embodiment except that the insulating layers 102 to 104 and the wiring layers 122 and 123 do not have a terrace portion in the hookup region HR. Therefore, the film thickness of the wiring layers 122 to 124 is substantially uniform over the entire wiring layers.

The configurations of the memory pillar MP1, the insulator 109, the conductors 125 and 126, and the conductive layer 127 are the same as those of the first embodiment.

Conductors 128 extend in the Z direction in the hookup region HR and penetrate the stacked wiring structure. One end of the conductor 128 reaches the semiconductor layer 121, for example. The other end of the conductor 128 reaches, for example, above the wiring layer 124 in the Z1 direction. The conductor 128 has a columnar shape and is used as the contact CC.

The insulator 107 is provided between the conductor 128 and the semiconductor layer 121. The insulator 107 includes, for example, silicon oxide. With this configuration, the conductor 128 is electrically insulated from the semiconductor layer 121.

The insulator 108 is provided between the conductor 128 and the wiring layers disposed lower than the corresponding wiring layer in the Z1 direction. With this configuration, the conductor 128 is electrically insulated from the wiring layers below the corresponding wiring layer in the Z1 direction among the wiring layers 122, 123, and 124.

The conductor 128 is in contact with the side surface of the corresponding wiring layer to be electrically connected to each other. A diameter of a contact portion of the conductor 128 with the corresponding wiring layer is larger than other portions of the conductor 128. The diameter of the contact portion of the conductor 128 with the corresponding wiring layer is, for example, equal to the diameter of the insulator 108.

In addition, an insulator 161, a conductor 162, and an insulator 163 are provided between the conductor 128 and a stacked wiring structure above the corresponding wiring layer in the Z1 direction.

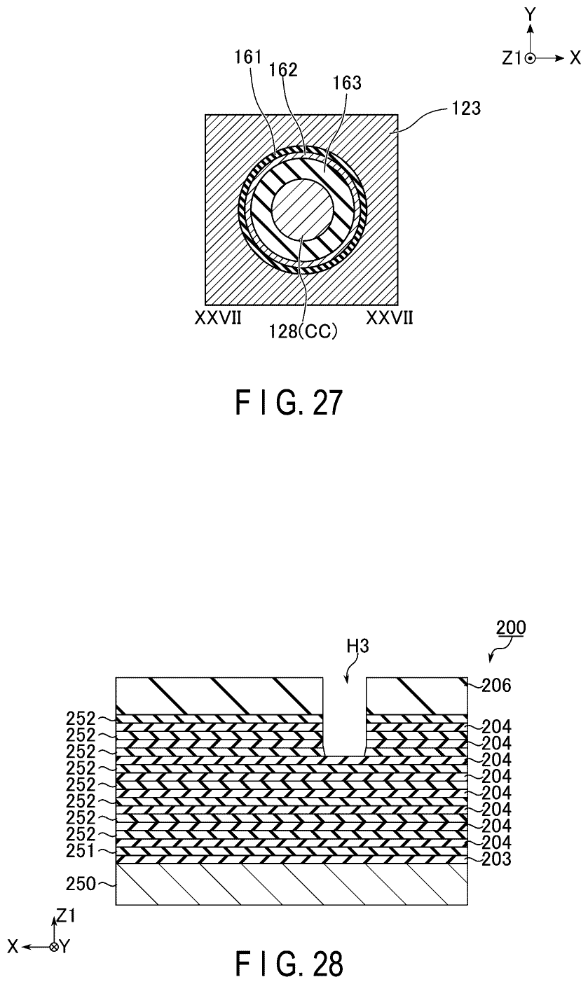

FIG. 27 is a cross-sectional view taken along a line XXVII-XXVII in FIG. 25 and illustrating an example of the cross-sectional structure of the contact included in the memory device according to the second embodiment. FIG. 27 illustrates a cross section parallel to the XY plane and including the contact CC and the wiring layers above the corresponding wiring layer in the Z1 direction.

As illustrated in FIG. 27, the insulator 163 surrounds a portion of the side surface of the conductor 128 above a connection portion with the wiring layer in the Z1 direction. The conductor 162 surrounds the side surface of the insulator 163. The end portion of the conductor 162 is in contact with each of the wiring layer and the conductor 128 at a connection portion between the conductor 128 and the wiring layer surrounded by the end portion. The conductor 162 is provided as a continuous film with the wiring layer to be connected. The insulator 161 surrounds the side surface of the conductor 162. Then, the stacked wiring structure above the wiring layer connected to the conductor 128 in the Z1 direction surrounds the side surface of the insulator 161.

With the above configuration, the conductor 128 is electrically insulated from the lower wiring layers in the Z1 direction from the wiring layer to be connected via the insulator 107, and is electrically insulated from the upper wiring layers via the insulator 161.

The configurations of the conductive layers 129 and 131, the conductor 130, and the insulating layers 105 and 106 are the same as those of the first embodiment.

Next, a cross-sectional structure of a memory chip 200 will be described.

The memory chip 200 includes a memory pillar MP2, insulating layers 201 to 207, insulators 208 to 211, 261, and 263, a semiconductor layer 222, wiring layers 223 to 225, conductive layers 221, 228, 231, and 233, and conductors 226, 227, 229, 230, 232, and 262.

The configurations of the insulating layers 201 and 202, the insulator 208, the conductive layer 221, the semiconductor layer 222, and the conductor 229 are the same as those of the first embodiment.

The configuration of the stacked wiring structure is the same as that of the first embodiment except that the insulating layer 203 to 205 and the wiring layers 223 and 224 do not have a terrace portion in the hookup region HR. Therefore, the film thickness of the wiring layers 223 to 225 is substantially uniform over the entire wiring layers.

The configurations of the memory pillar MP2, the insulator 211, the conductors 226 and 227, and the conductive layer 228 are the same as those of the first embodiment.

The conductor 230 extends in the Z direction in the hookup region HR and penetrates the stacked wiring structure. One end of the conductor 230 reaches the semiconductor layer 222, for example. The other end of the conductor 230 reaches, for example, above the wiring layer 225 in the Z1 direction. The conductor 230 has a columnar shape and is used as the contact CC.

The insulator 209 is provided between the conductor 230 and the semiconductor layer 222. The insulator 209 includes, for example, silicon oxide. With this configuration, the conductor 230 is electrically insulated from the semiconductor layer 222.

The insulator 210 is provided between the conductor 230 and the wiring layers disposed lower than the corresponding wiring layer in the Z1 direction. With this configuration, the conductor 230 is electrically insulated from the wiring layers below the corresponding wiring layer in the Z1 direction among the wiring layers 223, 224, and 25.

The conductors 230 are electrically connected to each other by being in contact with the side surface of the corresponding wiring layer. A diameter of a contact portion of the conductor 230 with the corresponding wiring layer is larger than other portions of the conductor 230. The film thickness of a portion having a diameter larger than that of the other portions of the conductor 230 is larger than the film thickness of the wiring layers, for example.

In addition, an insulator 261, a conductor 262, and an insulator 263 are provided between the conductor 230 and the stacked wiring structure above the corresponding wiring layer in the Z1 direction.

Similarly to the memory chip 100, the insulator 263 surrounds a portion of the side surface of the conductor 230 above the connection portion with the wiring layer in the Z1 direction. The conductor 262 surrounds a side surface of the insulator 263 and a side surface of a portion not in contact with the wiring layer in a portion having a diameter larger than that of the other portion of the conductor 230. The end portion of the conductor 262 is in contact with each of the wiring layer and the conductor 230 at a connection portion between the conductor 230 and the wiring layer surrounded by the end portion. The conductor 262 is provided as a continuous film with the wiring layer to be connected. The insulator 261 surrounds the side surface of the conductor 262. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

The configurations of the conductive layers 231 and 233, the conductor 232, and the insulating layers 206 and 207 of the memory chip 200, and the configuration of the circuit chip 300 are the same as those of the first embodiment.

With the above configuration, the specific word line WL of each of the memory chips 100 and 200 is electrically connected via the conductors 128 and 230, and is commonly connected to the transistor TR in the circuit chip 300.

### 2.3 Manufacturing Method

FIGS. 28 to 37 are cross-sectional views illustrating an example of a cross-sectional structure in a process of manufacturing the memory device according to the second embodiment. FIGS. 28 to 37 correspond to the memory chip 200 in the cross section illustrated in FIG. 26.

First, the memory chips 100 and 200 and the circuit chip 300 are individually formed. Focusing on the process of manufacturing the memory chip 200, a stacked structure corresponding to the stacked wiring structure is provided on the upper surface of the substrate 250 in the Z1 direction by a process similar to that of the first embodiment.

Subsequently, as illustrated in FIG. 28, the sacrificial member 253 and the insulating layers 204 in the hookup region HR are removed. Then, a hole H3 is formed in the region where the contact CC is to be formed. The hole H3 reaches the insulating layer provided on the upper surface in the Z1 direction of the sacrificial member located in the same layer as the wiring layer to which the corresponding contact CC is connected (the sacrificial member 252 of the fourth layer in a case of counting from the upper side in FIG. 28).

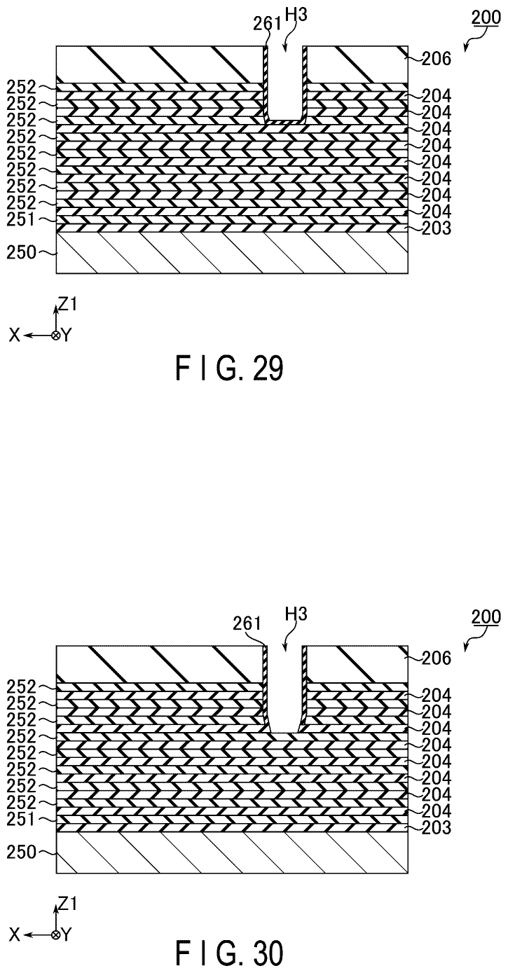

Subsequently, as illustrated in FIG. 29, the insulator 261 is formed in the hole H3. The insulator 261 includes, for example, silicon oxide.

Subsequently, as illustrated in FIG. 30, the bottom portion of the hole H3 is selectively etched, and the insulator 261 at the bottom portion of the hole H3 and the insulating layer on the lower surface of the insulator 261 in the Z1 direction are removed (the third insulating layer 204 in a case of counting from the upper side in FIG. 28). As a result, the sacrificial member located in the same layer as the wiring layer to which the corresponding contact CC is connected is exposed at the bottom of the hole H3.

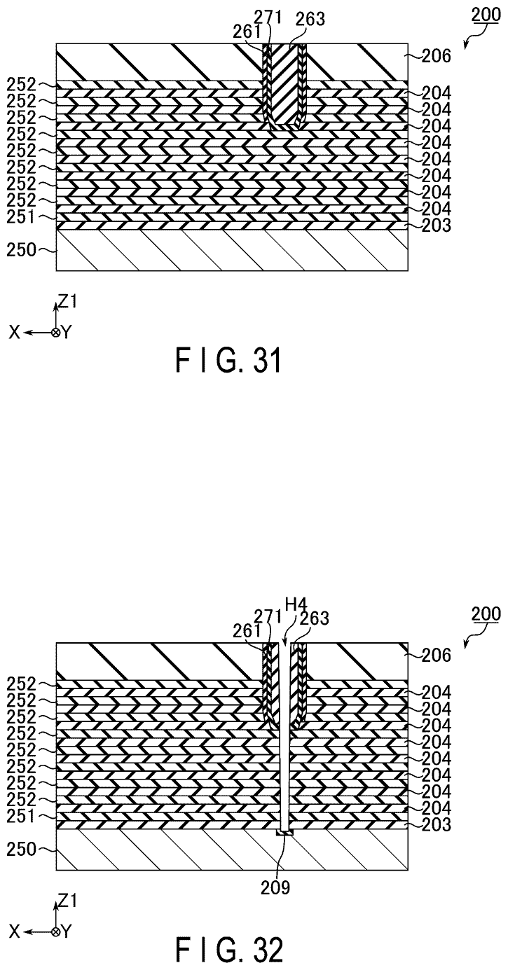

Subsequently, as illustrated in FIG. 31, the sacrificial member 271 and the insulator 263 are formed in this order in the hole H3, and the hole H3 is embedded. The sacrificial member 271 includes, for example, silicon nitride. The insulator 263 includes, for example, silicon oxide.

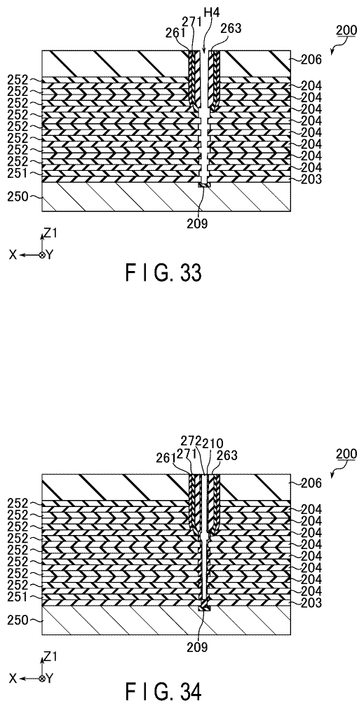

Subsequently, as illustrated in FIG. 32, a hole H4 is formed in a region where the contact CC is to be formed. The hole H4 penetrates the insulator 263, the sacrificial member 271, and the stacked structure and reaches the substrate 250. As a result, the substrate 250 is exposed at the bottom of the hole H4. Then, the insulator 209 is formed by oxidizing the portion of the substrate 250 exposed to the bottom portion of the hole H4. Subsequently, as illustrated in FIG. 33, the sacrificial members 251, 252, and 271 exposed in the hole H4 are partially removed by, for example, wet etching. As a result, recesses are formed in portions of the hole H4 where the respective sacrificial members 251, 252, and 271 are provided. In the hole H4, the sacrificial member 271 is in contact with the sacrificial member corresponding to the wiring layer to be connected to the contact CC. Therefore, the recess formed by removing the sacrificial member 271 and the sacrificial member in the stacked structure in contact with the sacrificial member 271 is larger than the other recesses by the film thickness of the sacrificial member 271 in the Z direction.

Subsequently, as illustrated in FIG. 34, the hole H4 is embedded by forming the insulator 210 and the sacrificial member 272 in this order in the hole H4. The sacrificial member 272 includes, for example, silicon. In the formation of the insulator 210, the recesses (small recesses) having the same size as the film thickness of the sacrificial members 251 and 252 are embedded by the insulator 210. On the other hand, recess (the large recess formed by removing the sacrificial member 252 and the sacrificial member 271 of the fourth layer in a case of counting from the upper side in FIG. 34) larger than the film thicknesses of the sacrificial members 251 and 252 are not fully embedded by the insulator 210.

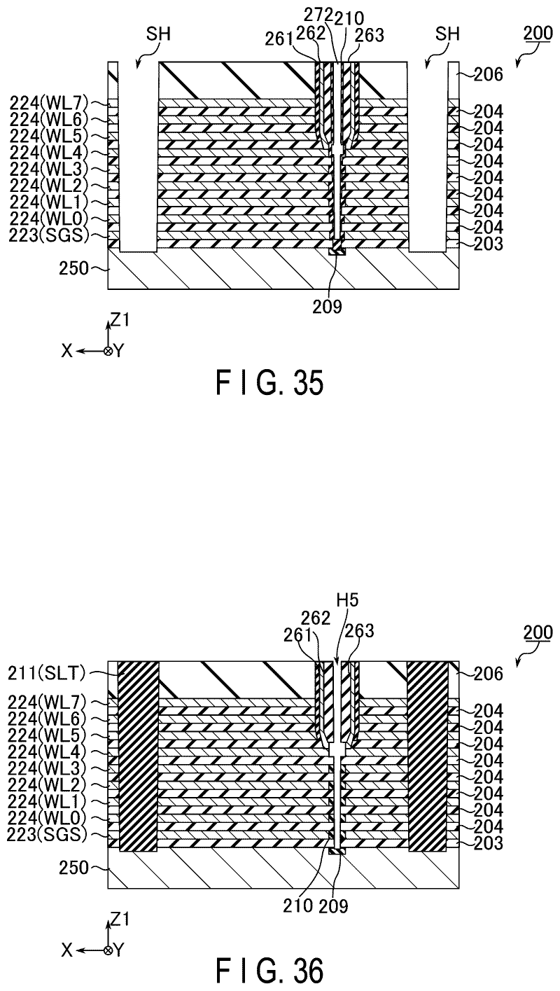

Subsequently, as illustrated in FIG. 35, slits SH are formed in regions where the members SLT are to be formed. The slits SH penetrate the insulating layer 206 and the stacked structure and reach the substrate 250. A replacement process of the stacked structure is executed through the slits SH. In the replacement process of the stacked structure, the sacrificial members 251, 252, 253, and 271 are selectively removed through the slits SH by wet etching using thermal phosphoric acid or the like. Then, the conductor is embedded in the space from which the sacrificial members 251, 252, 253, and 271 have been removed through the slits SH. Thereafter, the conductor formed inside the slits SH is removed by etch-back processing. As a result, the conductor formed inside the slits SH is separated into a plurality of conductive layers. As described above, the wiring layer 223 functioning as the select gate line SGS, the plurality of wiring layers 224 each functioning as the word line WL, and the wiring layer 225 functioning as the select gate line SGD are formed. After the replacement process in the stacked structure, the slits SH are embedded by the insulator 211, whereby the member SLT is formed.

In the replacement process described above, the sacrificial member 271 is replaced with the conductor 262. Therefore, the conductor 262 becomes a continuous film with the wiring layer obtained by replacing the sacrificial member disposed in the same layer as the large recess formed in the hole H4. As a result, the portion of the wiring layer to be connected to the contact CC is thickened.

Subsequently, as illustrated in FIG. 36, the sacrificial member 272 is removed to form a hole H5. Then, the insulator 210 is partially removed through the hole H5. In a case where the insulator 210 is removed, the portions of the insulator 210 that fill the small recesses in the hole H5 remain. On the other hand, the portion of the insulator 210 provided in the large recess in the hole H5 and the remaining portion of the insulator 210 are removed. As a result, in the hole H5, portions of the wiring layers 223 and 224 that are thickened are exposed, but portions that are not thickened are not exposed by the remaining insulator 210.

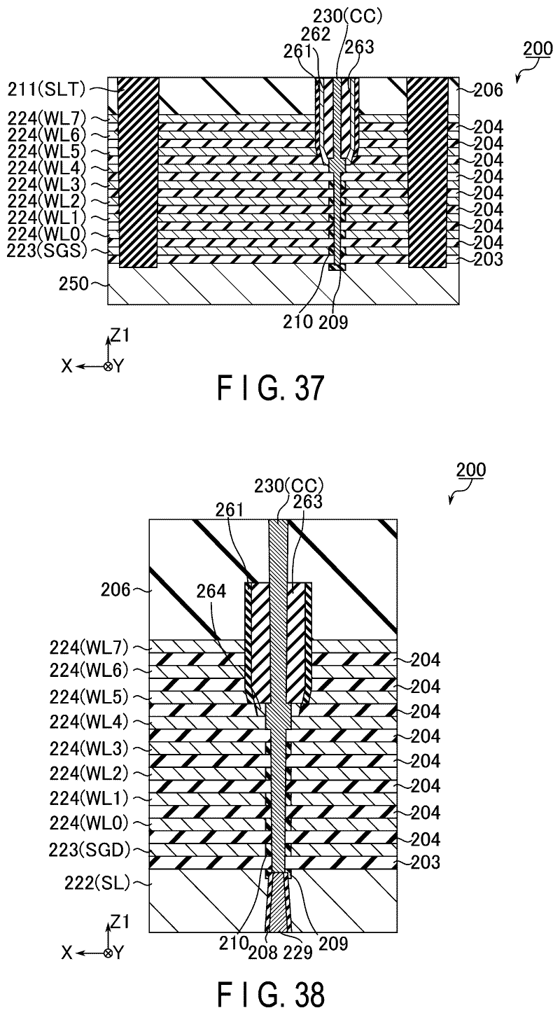

Subsequently, as illustrated in FIG. 37, the conductor 230 is embedded in the hole H5 to form the contact CC. The conductor 230 is selectively and electrically connected to the thickened wiring layer in the hole H5. On the other hand, the conductor 230 is electrically insulated by the insulator 210 with respect to the wiring layer which is not thickened in the hole H5. In addition, the conductor 230 is electrically insulated from the substrate 250 by the insulator 209 in the hole H5.

Thereafter, as in the first embodiment, the memory device 3 is formed through a process of bonding the circuit chip 300 and the memory chip 100.

### 2.4 Effects According to Second Embodiment

According to the second embodiment, as viewed in the Z direction, the wiring layer closer to the substrate 303 than the wiring layer in contact with the conductor 230 surrounds the portion of the conductor 230 closer to the substrate 303 than the wiring layer. The conductor 262 is in contact with the conductor 230 on the substrate 303 side with respect to the wiring layer in contact with the conductor 230, and is provided as a continuous film of the wiring layer. The conductor 262 is provided so as to cross the wiring layer closer to the substrate 303 than the wiring layer in contact with the conductor 230. As a result, the word line WL provided in the memory chip 100 and the word line WL provided in the memory chip 200 can be electrically connected by using the conductor 230 even for a stacked wiring structure having no staircase structure. Therefore, as in the first embodiment, the staircase structure provided in the memory chip 100 and the staircase structure provided in the memory chip 200 can be arranged at positions overlapping each other as viewed in the Z direction. Therefore, the degree of integration can be improved.

### 2.4 Modification of Second Embodiment

Various modifications can be applied to the second embodiment.

### 2.4.1 First Modification of Second Embodiment

According to the second embodiment, the case where the sacrificial member 271 is formed on the bottom surface and the side surface in the hole H3 and is replaced with the conductor 262 has been described, but the present invention is not limited thereto. For example, the sacrificial member replaced with the conductor in the hole H3 may not be provided on the side surface of the hole H3. Hereinafter, a configuration and a manufacturing method different from those of the second embodiment will be mainly described. Description of the same configuration and manufacturing method as those of the second embodiment will be omitted as appropriate.

### 2.4.1.1 Cross-Sectional Structure of Memory Device

FIG. 38 is a cross-sectional view illustrating an example of a cross-sectional structure of a memory device according to a first modification of the second embodiment. FIG. 38 corresponds to an enlarged view of the contact CC and its periphery in the memory chip 200 of FIG. 26 in the second embodiment. Note that the configuration of a portion of a memory chip 100 is also equivalent to the configuration illustrated in FIG. 38.

As illustrated in FIG. 38, according to the first modification of the second embodiment, the memory chip 200 includes insulating layers 203, 204, and 206, insulators 208, 209, 210, 261, and 263, a semiconductor layer 222, wiring layers 223 and 224, and conductors 229, 230, and 264 in the vicinity of the contact CC.

The configurations of the insulating layers 203, 204, and 206, the insulators 208, 209, and 210, the semiconductor layer 222, the wiring layers 223 and 224, and the conductor 229 are the same as those of the second embodiment.

The conductor 230 extends in the Z direction in the hookup region HR and penetrates the stacked wiring structure. One end of the conductor 230 reaches the semiconductor layer 222, for example. The other end of the conductor 230 reaches, for example, above the wiring layer 225 in the Z1 direction. The conductor 230 has a columnar shape and is used as the contact CC.

The insulator 209 is provided between the conductor 230 and the semiconductor layer 222. The insulator 209 includes, for example, silicon oxide. With this configuration, the conductor 230 is electrically insulated from the semiconductor layer 222.

The insulator 210 is provided between the conductor 230 and the wiring layers disposed lower than the corresponding wiring layer in the Z1 direction. With this configuration, the conductor 230 is electrically insulated from the wiring layers below the corresponding wiring layer in the Z1 direction among the wiring layers 223, 224, and 25.

The conductors 230 are electrically connected to each other by being in contact with the side surface of the corresponding wiring layer. A diameter of a contact portion of the conductor 230 with the corresponding wiring layer is larger than other portions of the conductor 230. The film thickness of a portion having a diameter larger than that of the other portions of the conductor 230 is larger than the film thickness of the wiring layers, for example.

In addition, an insulator 261, an insulator 263, and a conductor 264 are provided between the conductor 230 and a stacked wiring structure above the corresponding wiring layer in the Z1 direction.

The insulator 263 surrounds a portion of the side surface of the conductor 230 above the connection portion with the wiring layer in the Z1 direction. The insulator 261 surrounds a side surface of the insulator 263. Then, the stacked wiring structure above the wiring layer connected to the conductor 230 in the Z1 direction surrounds the side surface of the insulator 261. The conductor 264 surrounds the side surface of the conductor 230 so as to be in contact with both the conductor 230 and the wiring layer at the contact portion between the conductor 230 and the wiring layer. The conductor 264 is provided as a continuous film with the wiring layer to be connected.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.1.2 Manufacturing Method

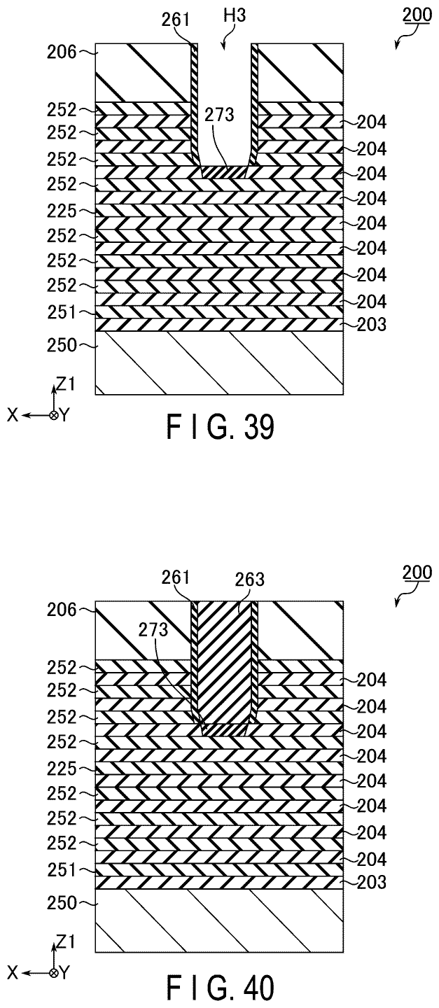

FIGS. 39 to 43 are cross-sectional views illustrating an example of a cross-sectional structure in a process of manufacturing the memory device according to the first modification of the second embodiment. FIGS. 39 to 43 correspond to FIG. 38.

First, a structure equivalent to that in FIG. 30 is formed by a process similar to those in the second embodiment. In other words, the hole H3 is formed in the region where the contact CC is to be formed in the stacked structure. After the insulator 261 is formed in the hole H3, the bottom portion of the hole H3 is etched to expose the sacrificial member immediately below the hole H3.

Subsequently, as illustrated in FIG. 39, a further sacrificial member 273 is selectively grown on the sacrificial member exposed at the bottom of the hole H3. The sacrificial member 273 includes, for example, silicon nitride. The film thickness of the sacrificial member 273 is, for example, equal to or less than the film thickness of the insulating layer 204 in the stacked structure.

Subsequently, as illustrated in FIG. 40, the hole H3 is embedded by forming the insulator 263 in the hole H3.

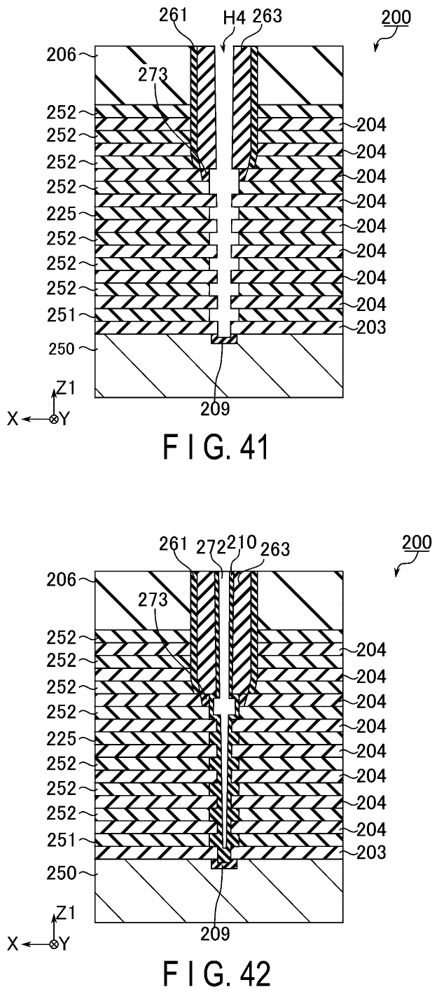

Subsequently, as illustrated in FIG. 41, a hole H4 is formed in a region where the contact CC is to be formed. The hole H4 penetrates the insulator 263, the sacrificial member 273, and the stacked structure and reaches the substrate 250. As a result, the substrate 250 is exposed at the bottom of the hole H4. Then, the insulator 209 is formed by oxidizing the portion of the substrate 250 exposed to the bottom portion of the hole H4. Thereafter, the sacrificial members 251 and 252 exposed in the hole H4 are partially removed by, for example, wet etching. As a result, a recess is formed in a portion where each of the sacrificial members 251 and 252 is provided in the hole H4. In the hole H4, the sacrificial member 273 is in contact with the sacrificial member corresponding to the wiring layer to be connected to the contact CC. Therefore, the recess formed by removing the sacrificial member 273 and the sacrificial member in the stacked structure in contact with the sacrificial member 273 is larger than the other recesses by the film thickness of the sacrificial member 273 in the Z direction.

Subsequently, as illustrated in FIG. 42, the hole H4 is embedded by forming the insulator 210 and the sacrificial member 272 in this order in the hole H4. In the formation of the insulator 210, the recesses (small recesses) having the same size as the film thickness of the sacrificial members 251 and 252 are embedded by the insulator 210. On the other hand, the recess larger than the film thicknesses of the sacrificial members 251 and 252 (the large recess formed by removing the sacrificial member 252 of the fourth layer in a case of counting from the upper side in FIG. 42 and the sacrificial member 251 in contact with the sacrificial member 252) is not fully embedded by the insulator 210.

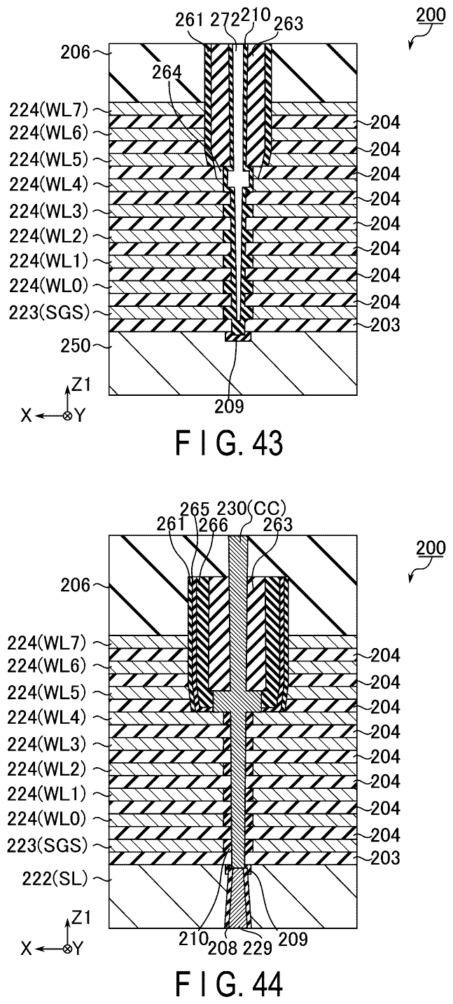

Subsequently, as illustrated in FIG. 43, a replacement process of the stacked structure is executed. As a result, the sacrificial members 251, 252, and 253 are replaced with the wiring layers 223, 224, and 225, respectively.

In the replacement process described above, the sacrificial member 273 is replaced with the conductor 264. Therefore, the conductor 264 becomes a continuous film with the wiring layer disposed in the same layer as the large recess formed in the hole H4. As a result, the portion of the wiring layer to be connected to the contact CC is thickened.

Thereafter, similarly to the second embodiment, the sacrificial member 272 and a part of the insulator 210 are removed to form the contact CC. Then, the memory device 3 is formed through a process of bonding the circuit chip 300 and the memory chip 100.

### 2.4.1.3 Effects According to First Modification of Second Embodiment

According to the first modification of the second embodiment, the sacrificial member 273 is formed by selective growth. With this configuration, the conductor 264 provided by replacing the sacrificial member 273 is provided so as not to cross the wiring layer on the substrate 303 side with respect to the wiring layer in contact with the conductor 230. Therefore, it is possible to suppress the formation of the conductor in the structure provided between the stacked wiring and the portion of the conductor 230 closer to the substrate 303 than the portion in contact with the corresponding wiring layer. Therefore, an unintended short circuit between the conductor and the wiring layer can be suppressed.

### 2.4.2 Second Modification of Second Embodiment

According to the second embodiment, the case where the contact CC and the wiring layer are connected on the side surface has been described, but the present invention is not limited thereto. For example, the contact CC may be connected to the upper surface of the wiring layer. Hereinafter, a configuration and a manufacturing method different from those of the second embodiment will be mainly described. Description of the same configuration and manufacturing method as those of the second embodiment will be omitted as appropriate.

### 2.4.2.1 Cross-Sectional Structure of Memory Device

FIG. 44 is a cross-sectional view illustrating an example of a cross-sectional structure of a memory device according to a second modification of the second embodiment. FIG. 44 corresponds to an enlarged view of the contact CC and its periphery in the memory chip 200 of FIG. 26 in the second embodiment. Note that the configuration of a portion of a memory chip 100 is also equivalent to the configuration illustrated in FIG. 44.

As illustrated in FIG. 44, according to the second modification of the second embodiment, the memory chip 200 includes insulating layers 203, 204, and 206, insulators 208, 209, 210, 261, 263, and 265, a sacrificial member 266, a semiconductor layer 222, wiring layers 223 and 224, and conductors 229 and 230 in the vicinity of the contact CC.

The configurations of the insulating layers 203, 204, and 206, the insulators 208, 209, and 210, the semiconductor layer 222, the wiring layers 223 and 224, and the conductor 229 are the same as those of the second embodiment.

The conductor 230 extends in the Z direction in the hookup region HR and penetrates the stacked wiring structure. One end of the conductor 230 reaches the semiconductor layer 222, for example. The other end of the conductor 230 reaches, for example, above the wiring layer 225 in the Z1 direction. The conductor 230 has a columnar shape and is used as the contact CC.

The insulator 209 is provided between the conductor 230 and the semiconductor layer 222. The insulator 209 includes, for example, silicon oxide. With this configuration, the conductor 230 is electrically insulated from the semiconductor layer 222.

An insulator 210 is provided between the conductor 230 and the corresponding wiring layer and a wiring layer below the corresponding wiring layer in the Z1 direction. With this configuration, the conductor 230 is electrically insulated from the wiring layers below the corresponding wiring layer in the Z1 direction among the wiring layers 223, 224, and 225. In the same layer as the corresponding wiring layer, the conductor 230 is provided away from the wiring layer via the insulator 210.

The conductor 230 is electrically connected to each other by being in contact with the upper surface of the corresponding wiring layer in the Z1 direction. The diameter of the contact portion of the conductor 230 with the corresponding wiring layer is larger than the diameter of the insulator 210, for example. The film thickness of the portion of the conductor 230 having a diameter larger than that of the insulator 210 is larger than the film thickness of the wiring layer, for example.

In addition, the insulators 261, 263, and 265 and the sacrificial member 266 are provided between the conductor 230 and the stacked wiring structure above the corresponding wiring layer in the Z1 direction.

The insulator 263 surrounds a portion of the side surface of the conductor 230 above the connection portion with the wiring layer in the Z1 direction. The sacrificial member 266 surrounds the side surface of the insulator 263 and the side surface of the conductor 230 at the connection portion with the wiring. The insulator 265 surrounds the side surface of the sacrificial member 266. The insulator 261 surrounds a side surface of the insulator 265. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.2.2 Manufacturing Method

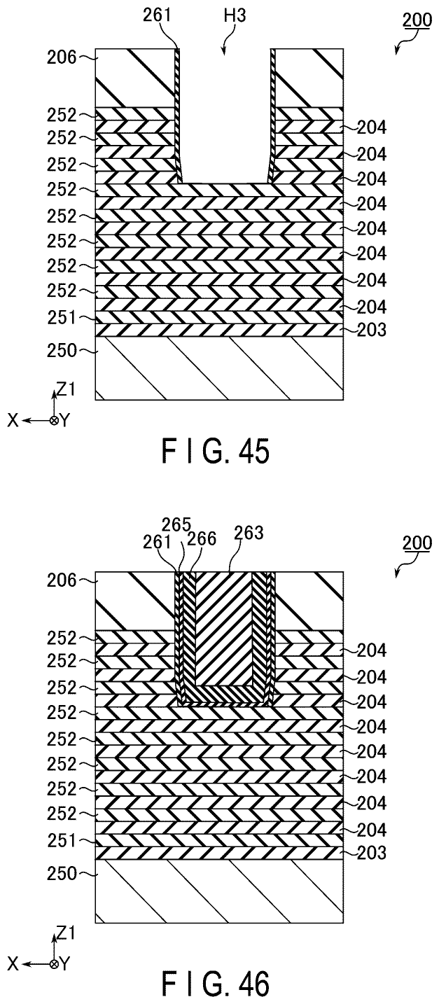

FIGS. 45 to 50 are cross-sectional views illustrating an example of a cross-sectional structure in a process of manufacturing the memory device according to the second modification of the second embodiment. FIGS. 45 to 50 correspond to FIG. 44.

First, a stacked structure is formed by the same process as in the second embodiment.

Subsequently, as illustrated in FIG. 45, the hole H3 is formed in a region of the stacked structure where the contact CC is to be formed. A sacrificial member corresponding to the wiring layer to be connected to the contact CC is exposed at the bottom of the hole H3. Then, after the insulator 261 is formed in the hole H3, the bottom portion of the hole H3 is etched to expose the sacrificial member immediately below the hole H3.

Subsequently, as illustrated in FIG. 46, the insulator 265, the sacrificial member 266, and the insulator 263 are formed in this order in the hole H3, whereby the hole H3 is embedded. The insulator 265 includes, for example, silicon oxide. The sacrificial member 266 includes, for example, silicon nitride. The film thickness of the sacrificial member 266 is, for example, larger than the film thickness of the insulating layer 204 in the stacked structure.

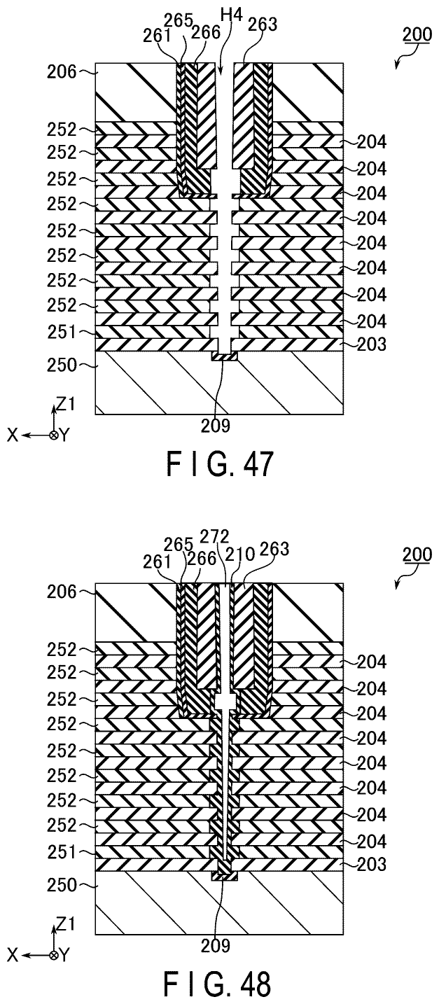

Subsequently, as illustrated in FIG. 47, a hole H4 is formed in a region where the contact CC is to be formed. The hole H4 penetrates the insulator 263, the sacrificial member 266, the insulator 265, and the stacked structure and reaches the substrate 250. As a result, the substrate 250 is exposed at the bottom of the hole H4. Then, the insulator 209 is formed by oxidizing the portion of the substrate 250 exposed to the bottom portion of the hole H4. Thereafter, each sacrificial member exposed in the hole H4 is partially removed by, for example, wet etching. As a result, a recess is formed in a portion where each sacrificial member is provided in the hole H4. As described above, the film thickness of the sacrificial member 266 is larger than the film thickness of the sacrificial member in the stacked structure. Therefore, the recess formed by removing the sacrificial member 266 is larger than the other recesses in the Z direction.

Subsequently, as illustrated in FIG. 48, the hole H4 is embedded by forming the insulator 210 and the sacrificial member 272 in this order in the hole H4. In the formation of the insulator 210, small recesses having the same size as the film thickness of the sacrificial members 251 and 252 are embedded by the insulator 210. On the other hand, a large recess having the same size as the film thickness of the sacrificial member 266 is not fully embedded by the insulator 210.

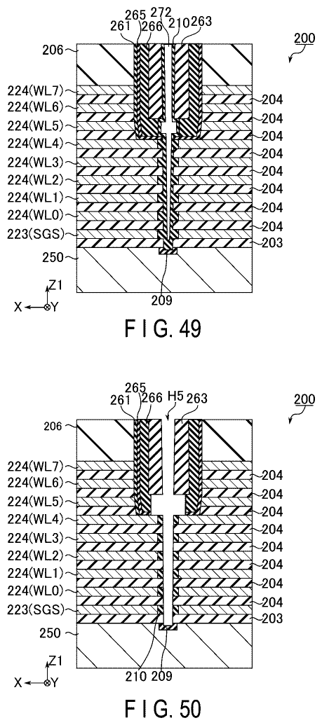

Subsequently, as illustrated in FIG. 49, a replacement process of the stacked structure is executed. As a result, the sacrificial members 251, 252, and 253 are replaced with the wiring layers 223, 224, and 225, respectively.

Subsequently, as illustrated in FIG. 50, the sacrificial member 272 is removed to form a hole H5. Then, the insulator 210 is partially removed through the hole H5. In a case where the insulator 210 is removed, the portions of the insulator 210 that fill the small recesses in the hole H5 remain. On the other hand, the portion of the insulator 210 provided in the large recess in the hole H5 and the remaining portion of the insulator 210 are removed. As a result, in the hole H5, the sacrificial member 266 is exposed, but the wiring layers 223 and 224 are not exposed. Thereafter, the sacrificial member 266 and the insulator 265 are further partially removed. As a result, the upper surface of the wiring layer in the Z1 direction is exposed to the space formed by removing the sacrificial member 266 and the insulator 265.

Thereafter, the inside of the hole H5 is embedded by the conductor 230 to form the contact CC. As a result, the conductor 230 is in contact with the portion exposed in the hole H5 of the corresponding wiring layer. Then, as in the second embodiment, the memory device 3 is formed through the process of bonding the circuit chip 300 and the memory chip 100.

### 2.4.2.3 Effects According to Second Modification of Second Embodiment

According to the second modification of the second embodiment, the sacrificial member 266 is in contact with the conductor 230 on the substrate 303 side with respect to the wiring layer in contact with the conductor 230. In this manner, the conductor 230 is provided so as to fill the space from which a part of the sacrificial member 266 has been removed. As a result, the diameter of the conductor 230 at the portion electrically connected to the wiring layer can be made larger than that of the other portions of the conductor 230. Therefore, the conductor 230 can be in contact with the surface of the wiring layer on the substrate 303 side.

In addition, the insulator 263 is provided between the conductor 230 and the sacrificial member 266 as viewed in the Z direction. As a result, a portion having a large diameter in the conductor 230 can be limited to a portion in contact with the wiring layer.

### 2.4.3 Third Modification of Second Embodiment

According to the second modification of the second embodiment, the case where the insulator 263 is provided on the side surface of the contact CC has been described, but the present invention is not limited thereto. For example, a sacrificial member 266 may be provided on a side surface of the contact CC. Hereinafter, a configuration and a manufacturing method different from those of the second modification of the second embodiment will be mainly described. Description of configurations and manufacturing methods equivalent to those of the modification of the second embodiment will be omitted as appropriate.

### 2.4.3.1 Cross-Sectional Structure of Memory Device

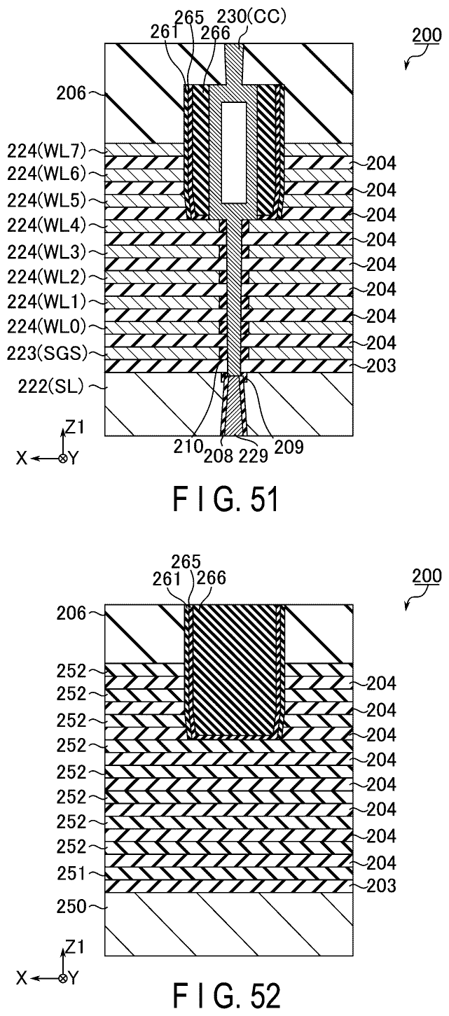

FIG. 51 is a cross-sectional view illustrating an example of a cross-sectional structure of a memory device according to the third modification of the second embodiment. FIG. 51 corresponds to FIG. 44 in the second modification of the second embodiment. Note that the configuration of a portion of a memory chip 100 is also equivalent to the configuration illustrated in FIG. 51.

As illustrated in FIG. 51, in the third modification of the second embodiment, a memory chip 200 includes insulating layers 203, 204, and 206, insulators 208, 209, 210, 261, and 265, a sacrificial member 266, a semiconductor layer 222, wiring layers 223 and 224, and conductors 229 and 230 in the vicinity of the contact CC.

The configurations of the insulating layers 203, 204, and 206, the insulators 208, 209, and 210, the semiconductor layer 222, the wiring layers 223 and 224, and the conductor 229 are the same as those of the second modification of the second embodiment.

The conductor 230 extends in the Z direction in the hookup region HR and penetrates the stacked wiring structure. One end of the conductor 230 reaches the semiconductor layer 222, for example. The other end of the conductor 230 reaches, for example, above the wiring layer 225 in the Z1 direction. The conductor 230 has a columnar shape and is used as the contact CC.

The insulator 209 is provided between the conductor 230 and the semiconductor layer 222. The insulator 209 includes, for example, silicon oxide. With this configuration, the conductor 230 is electrically insulated from the semiconductor layer 222.

An insulator 210 is provided between the conductor 230 and the corresponding wiring layer and a wiring layer below the corresponding wiring layer in the Z1 direction. With this configuration, the conductor 230 is electrically insulated from the wiring layers below the corresponding wiring layer in the Z1 direction among the wiring layers 223, 224, and 25. In the same layer as the corresponding wiring layer, the conductor 230 is provided away from the wiring layer via the insulator 210.

The conductor 230 is electrically connected to each other by being in contact with the upper surface of the corresponding wiring layer in the Z1 direction. The diameter of the contact portion of the conductor 230 with the corresponding wiring layer is larger than the diameter of the insulator 210, for example. The film thickness of the portion of the conductor 230 having a diameter larger than that of the insulator 210 is, for example, equivalent to the film thickness of the stacked wiring structure above the corresponding wiring layer in the Z1 direction.

In addition, insulators 261 and 265 and a sacrificial member 266 are provided between the conductor 230 and the stacked wiring structure above the corresponding wiring layer in the Z1 direction.

The sacrificial member 266 surrounds a portion of the side surface of the conductor 230 above the connection portion with the wiring layer in the Z1 direction. The insulator 265 surrounds the side surface of the sacrificial member 266. The insulator 261 surrounds a side surface of the insulator 265. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.3.2 Manufacturing Method

FIGS. 52 to 56 are cross-sectional views illustrating an example of a cross-sectional structure in a process of manufacturing the memory device according to the third modification of the second embodiment. FIGS. 52 to 56 correspond to FIG. 51.

First, a hole is formed in a region of the stacked structure where a contact CC is to be formed by a process similar to that of the second modification of the second embodiment. A sacrificial member corresponding to the wiring layer to be connected to the contact CC is exposed at the bottom of the hole. Then, after the insulator 261 is formed in the hole, the bottom portion of the hole is etched to expose the sacrificial member immediately below the hole.

Subsequently, as illustrated in FIG. 52, the hole is embedded by forming the insulator 265 and the sacrificial member 266 in a hole H3 in this order. The film thickness of the sacrificial member 266 is, for example, equivalent to the film thickness of the layer portion above, in the Z1 direction, the sacrificial member corresponding to the wiring layer to be connected to the contact CC in the stacked structure.

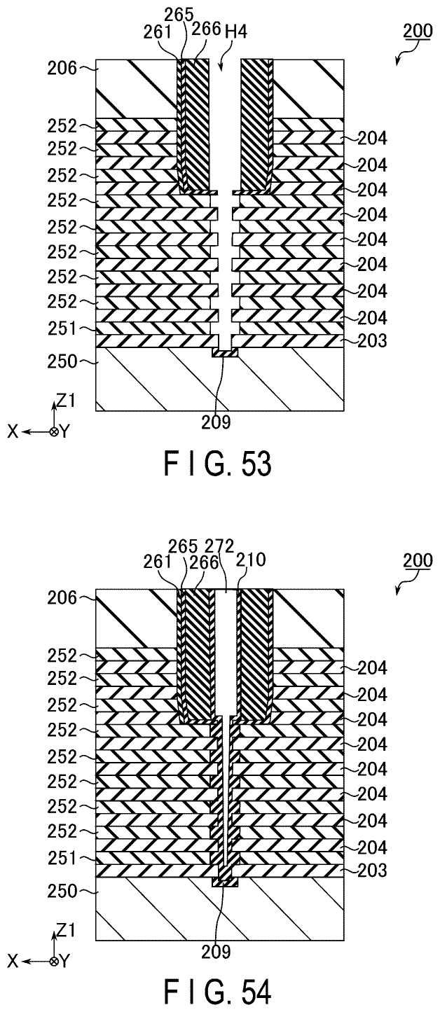

Subsequently, as illustrated in FIG. 53, a hole H4 is formed in a region where the contact CC is to be formed. The hole H4 penetrates the sacrificial member 266, the insulator 265, and the stacked structure and reaches the substrate 250. As a result, the substrate 250 is exposed at the bottom of the hole H4. Then, the insulator 209 is formed by oxidizing the portion of the substrate 250 exposed to the bottom portion of the hole H4. Thereafter, each sacrificial member exposed in the hole H4 is partially removed by, for example, wet etching. As a result, a recess is formed in a portion where each sacrificial member is provided in the hole H4. As described above, the film thickness of the sacrificial member 266 is relevant to the film thickness of the layer portion above, in the Z1 direction, the sacrificial member corresponding to the wiring layer to be connected to the contact CC in the stacked structure. Therefore, the recess formed by removing the sacrificial member 266 is larger than the other recesses in the Z direction.

Subsequently, as illustrated in FIG. 54, the hole H4 is embedded by forming the insulator 210 and the sacrificial member 272 in this order in the hole H4. In the formation of the insulator 210, the recesses (small recesses) having the same size as the film thickness of the sacrificial members 251 and 252 are embedded by the insulator 210. On the other hand, the recess (a large recess) having the same size as the film thickness of the sacrificial member 266 is not fully embedded by the insulator 210.

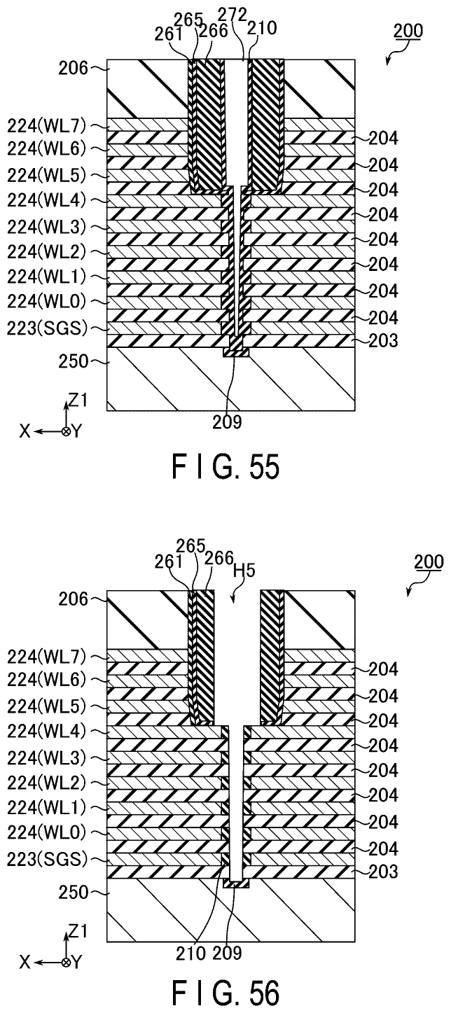

Subsequently, as illustrated in FIG. 55, a replacement process of the stacked structure is executed. As a result, the sacrificial members 251, 252, and 253 are replaced with the wiring layers 223, 224, and 225, respectively.

Subsequently, as illustrated in FIG. 56, the sacrificial member 272 is removed to form the hole H5. Then, the insulator 210 is partially removed through the hole H5. In a case where the insulator 210 is removed, the portions of the insulator 210 that fill the small recesses in the hole H5 remain. On the other hand, the portion of the insulator 210 provided in the large recess in the hole H5 and the remaining portion of the insulator 210 are removed. As a result, in the hole H5, the sacrificial member 266 is exposed, but the wiring layers 223 and 224 are not exposed. Thereafter, the sacrificial member 266 and the insulator 265 are further partially removed. As a result, the upper surface of the wiring layer in the Z1 direction is exposed to the space formed by removing the sacrificial member 266 and the insulator 265.

Thereafter, the inside of the hole H5 is embedded by the conductor 230 to form the contact CC. Then, as in the second embodiment, the memory device 3 is formed through the process of bonding the circuit chip 300 and the memory chip 100.

### 2.4.3.3 Effects According to Third Modification of Second Embodiment

According to the third modification of the second embodiment, the sacrificial member 266 is in contact with the conductor 230 over both ends in the Z direction. Thus, the process of forming the insulator 263 in the hole H3 can be omitted.

### 2.4.4 Fourth Modification of Second Embodiment

In addition, according to the second embodiment, the case of executing the process of replacing the sacrificial member 251 with the conductor 262 at the time of the process of replacing the sacrificial members 271, 252, and 253 with the wiring layers 223, 224, and 225 has been described, but the present invention is not limited thereto. For example, by applying a sacrificial member containing a material different from that of the sacrificial members 251, 252, and 253 instead of the sacrificial member 271, the replacement process of the sacrificial member may be executed at a timing different from the replacement process of the sacrificial members 251, 252, and 253. Hereinafter, a configuration and a manufacturing method different from those of the second embodiment will be mainly described. Description of the same configuration and manufacturing method as those of the second embodiment will be omitted as appropriate.

### 2.4.4.1 Cross-Sectional Structure of Memory Device

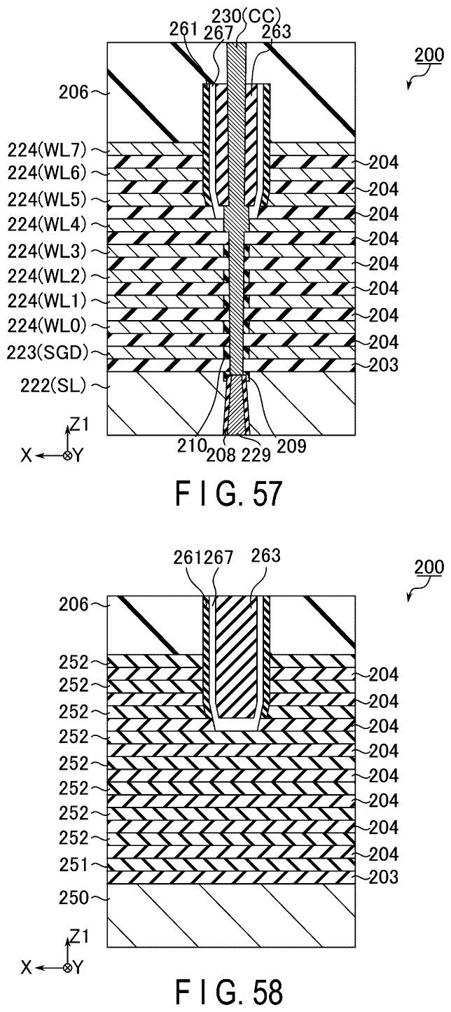

FIG. 57 is a cross-sectional view illustrating an example of a cross-sectional structure of the memory device according to the fourth modification of the second embodiment. FIG. 57 corresponds to an enlarged view of the contact CC and its periphery in the memory chip 200 of FIG. 26 in the second embodiment. Note that the configuration of the portion of the memory chip 100 is also equivalent to the configuration illustrated in FIG. 57.

As illustrated in FIG. 57, in the fourth modification of the second embodiment, the memory chip 200 includes insulating layers 203, 204, and 206, insulators 208, 209, 210, 261, and 263, a sacrificial member 267, a semiconductor layer 222, wiring layers 223 and 224, and conductors 229 and 230 around the contact CC.

The configurations of the insulating layers 203, 204, and 206, the insulators 208, 209, and 210, the semiconductor layer 222, the wiring layers 223 and 224, and the conductor 229 are the same as those of the second embodiment.

The conductor 230 extends in the Z direction in the hookup region HR and penetrates the stacked wiring structure. One end of the conductor 230 reaches the semiconductor layer 222, for example. The other end of the conductor 230 reaches, for example, above the wiring layer 225 in the Z1 direction. The conductor 230 has a columnar shape and is used as the contact CC.

The insulator 209 is provided between the conductor 230 and the semiconductor layer 222. The insulator 209 includes, for example, silicon oxide. With this configuration, the conductor 230 is electrically insulated from the semiconductor layer 222.

The insulator 210 is provided between the conductor 230 and the wiring layers disposed lower than the corresponding wiring layer in the Z1 direction. With this configuration, the conductor 230 is electrically insulated from the wiring layers below the corresponding wiring layer in the Z1 direction among the wiring layers 223, 224, and 25.

The conductors 230 are electrically connected to each other by being in contact with the side surface of the corresponding wiring layer. A diameter of a contact portion of the conductor 230 with the corresponding wiring layer is larger than other portions of the conductor 230. The film thickness of a portion having a diameter larger than that of the other portions of the conductor 230 is larger than the film thickness of the wiring layers, for example.

In addition, insulators 261 and 263 and a sacrificial member 267 are provided between the conductor 230 and the stacked wiring structure above the corresponding wiring layer in the Z1 direction.

The insulator 263 surrounds a portion of the side surface of the conductor 230 above the connection portion with the wiring layer in the Z1 direction. The sacrificial member 267 surrounds a side surface of the insulator 263 and a side surface of a portion not in contact with the wiring layer in a portion having a diameter larger than that of the other portion of the conductor 230. The insulator 261 surrounds the side surface of the sacrificial member 267. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.4.2 Manufacturing Method

FIGS. 58 to 63 are cross-sectional views illustrating an example of a cross-sectional structure in a process of manufacturing the memory device according to the fourth modification of the second embodiment. FIGS. 58 to 63 correspond to FIG. 57.

First, a structure equivalent to that in FIG. 30 is formed by a process similar to those in the second embodiment. In other words, the hole H3 is formed in the region where the contact CC is to be formed in the stacked structure. After the insulator 261 is formed in the hole H3, the bottom portion of the hole H3 is etched to expose the sacrificial member immediately below the hole H3.

Subsequently, as illustrated in FIG. 58, the sacrificial member 267 and the insulator 263 are formed in this order in the hole H3, whereby the hole H3 is embedded. The sacrificial member 267 includes, for example, silicon or silicon oxycarbide (SiOC).

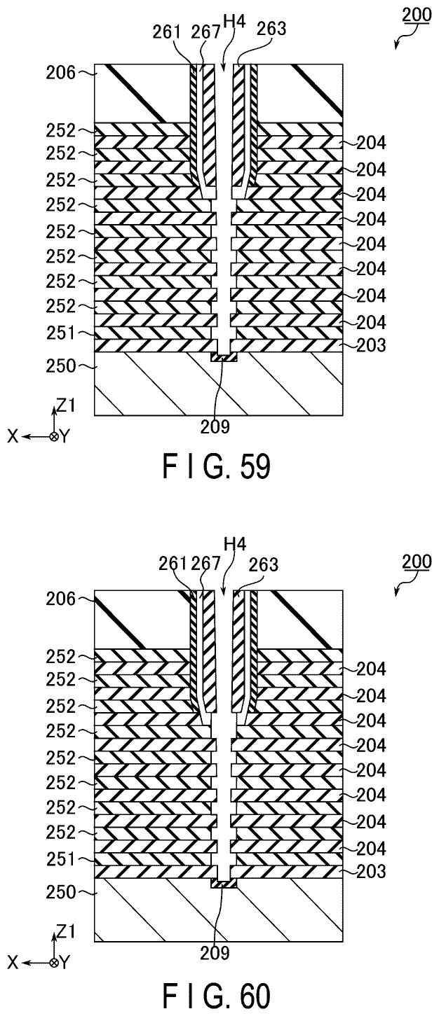

Subsequently, as illustrated in FIG. 59, a hole H4 is formed in a region where the contact CC is to be formed. The hole H4 penetrates the insulator 263, the sacrificial member 267, and the stacked structure and reaches the substrate 250. As a result, the substrate 250 is exposed at the bottom of the hole H4. Then, the insulator 209 is formed by oxidizing the portion of the substrate 250 exposed to the bottom portion of the hole H4. Thereafter, the sacrificial members 251 and 252 exposed in the hole H4 are partially removed by, for example, wet etching. As a result, a recess is formed in a portion where each of the sacrificial members 251 and 252 is provided in the hole H4. The sacrificial member 267 is not removed by selective etching of the sacrificial members 251 and 252.

Subsequently, as illustrated in FIG. 60, the sacrificial member 267 exposed in the hole H4 is partially removed by, for example, wet etching. In the hole H4, the sacrificial member 267 is in contact with the sacrificial member corresponding to the wiring layer to be connected to the contact CC. Therefore, the recess formed by removing the sacrificial member in the stacked structure in contact with the sacrificial member 267 and the sacrificial member 267 is larger than the other recesses by the film thickness of the sacrificial member 267 in the Z direction.

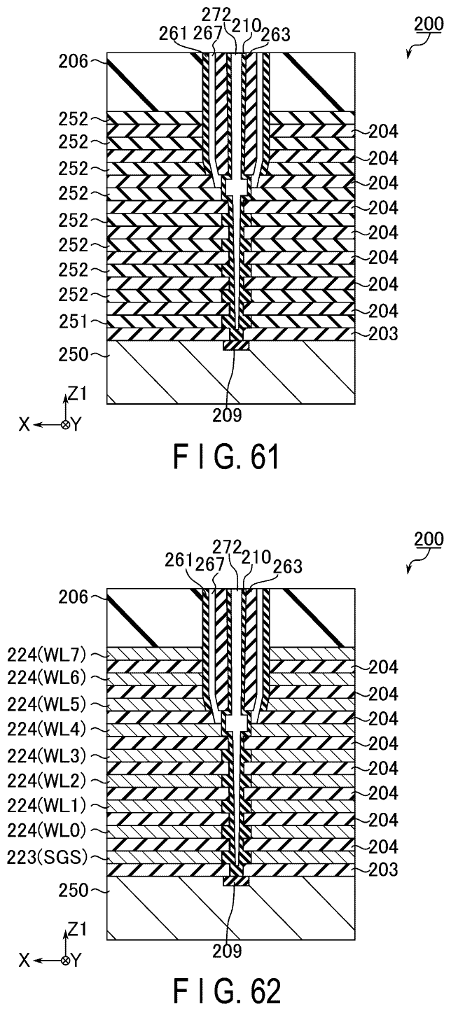

Subsequently, as illustrated in FIG. 61, the hole H4 is embedded by forming the insulator 210 and the sacrificial member 272 in this order in the hole H4. In the formation of the insulator 210, the recesses (small recesses) having the same size as the film thickness of the sacrificial members 251 and 252 are embedded by the insulator 210. On the other hand, the recess larger than the film thicknesses of the sacrificial members 251 and 252 (the large recess formed by removing the sacrificial member 252 of the fourth layer in a case of counting from the upper side in FIG. 61 and the sacrificial member 267 in contact with the sacrificial member 252) is not fully embedded by the insulator 210.

Subsequently, as illustrated in FIG. 62, a replacement process of the stacked structure is executed. As a result, the sacrificial members 251, 252, and 253 are replaced with the wiring layers 223, 224, and 225, respectively. In the replacement process described above, the sacrificial member 267 is not replaced. Therefore, the portion of the wiring layer to be connected to the contact CC is not thickened similarly to the other wiring layers.

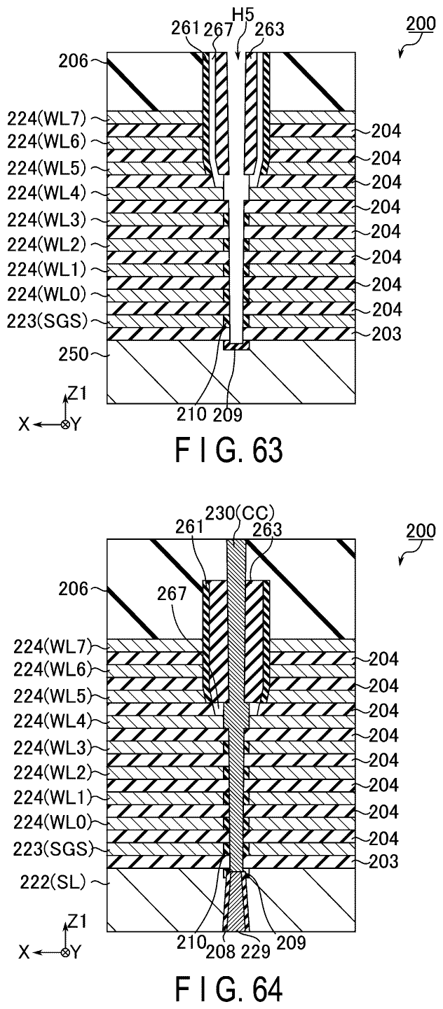

Subsequently, as illustrated in FIG. 63, the sacrificial member 272 is removed to form a hole H5. Then, the insulator 210 is partially removed through the hole H5. In a case where the insulator 210 is removed, the portions of the insulator 210 that fill the small recesses in the hole H5 remain. On the other hand, the portion of the insulator 210 provided in the large recess in the hole H5 and the remaining portion of the insulator 210 are removed. As a result, in the hole H5, the wiring layer to be connected to the contact CC is exposed, but the other wiring layers are not exposed.

Thereafter, the conductor 230 is formed in the hole H5 to form the contact CC. Then, as in the second embodiment, the memory device 3 is formed through the process of bonding the circuit chip 300 and the memory chip 100.

### 2.4.4.3 Effects According to Fourth Modification of Second Embodiment

According to the fourth modification of the second embodiment, the sacrificial member 267 is in contact with the conductor 230 and the wiring layer on the substrate 303 side with respect to the wiring layer in contact with the conductor 230. The sacrificial member 267 includes silicon or silicon oxycarbide. With this configuration, the sacrificial member 267 can be removed in a process different from the process for the sacrificial members 251, 252, and 253. Therefore, in the process of replacing the sacrificial members 251, 252, and 253 with the wiring layers 223, 224, and 225, the sacrificial member 267 remains without being removed. Then, the sacrificial member 267 can be selectively removed by a desired amount through the hole H5. Therefore, the shape of the contact portion of the conductor 230 with the wiring layer can be easily processed.

### 2.4.5 Fifth Modification of Second Embodiment

According to the fourth modification of the second embodiment, the case where the sacrificial member 267 is formed on the bottom surface and the side surface in the hole H3 has been described, but the present invention is not limited thereto. For example, the sacrificial member 267 may not be provided on the side surface of the hole H3. Hereinafter, a configuration and a manufacturing method different from those of the fourth modification of the second embodiment will be mainly described. Description of the same configuration and manufacturing method as those of the fourth modification of the second embodiment will be omitted as appropriate.

### 2.4.5.1 Cross-Sectional Structure of Memory Device

FIG. 64 is a cross-sectional view illustrating an example of a cross-sectional structure of a memory device according to a fifth modification of the second embodiment. FIG. 64 corresponds to FIG. 57 in the fourth modification of the second embodiment. Note that the configuration of the portion of a memory chip 100 is also equivalent to the configuration illustrated in FIG. 64.

As illustrated in FIG. 64, according to the fifth modification of the second embodiment, the memory chip 200 includes insulating layers 203, 204, and 206, insulators 208, 209, 210, 261, and 263, a sacrificial member 267, a semiconductor layer 222, wiring layers 223 and 224, and conductors 229 and 230 in the vicinity of the contact CC.

The configurations of the insulating layers 203, 204, and 206, the insulators 208, 209, and 210, the semiconductor layer 222, the wiring layers 223 and 224, and the conductors 229 and 230 are the same as those of the fourth modification of the second embodiment.

Insulators 261 and 263 and a sacrificial member 267 are provided between the conductor 230 and the stacked wiring structure above the corresponding wiring layer in the Z1 direction.

The insulator 263 surrounds a portion of the side surface of the conductor 230 above the connection portion with the wiring layer in the Z1 direction. The sacrificial member 267 surrounds a side surface of a portion not in contact with the wiring layer in a portion having a larger diameter than the other portion of the conductor 230. The insulator 261 surrounds a side surface of the insulator 261. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.5.2 Manufacturing Method

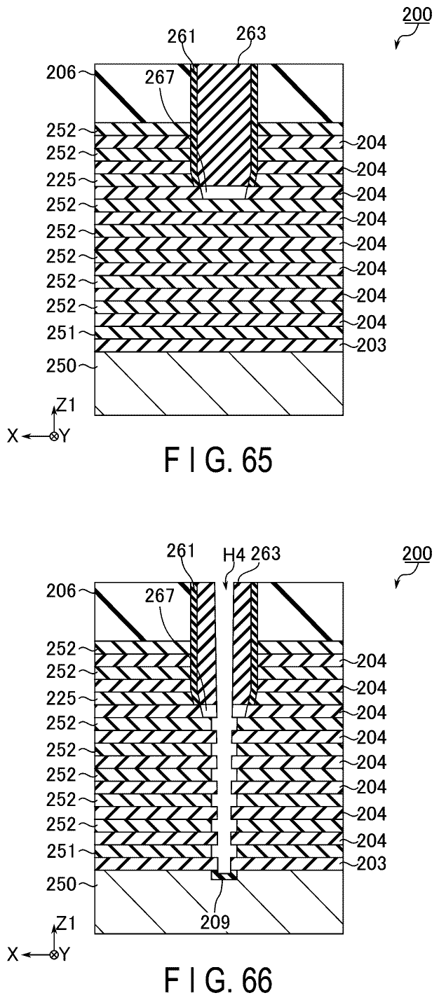

FIGS. 65 to 67 are cross-sectional views illustrating an example of a cross-sectional structure in a process of manufacturing the memory device according to the fifth modification of the second embodiment. FIGS. 65 to 67 correspond to FIG. 64.

First, a structure equivalent to that in FIG. 30 is formed by a process similar to those in the second embodiment. In other words, the hole H3 is formed in the region where the contact CC is to be formed in the stacked structure. After the insulator 261 is formed in the hole H3, the bottom portion of the hole H3 is etched to expose the sacrificial member immediately below the hole H3.

Subsequently, as illustrated in FIG. 65, the sacrificial member 267 is selectively grown in the hole H3. Then, the hole H3 is embedded by forming the insulator 263 in the hole H3. The sacrificial member 267 includes, for example, silicon or silicon oxycarbide (SiOC).

Subsequently, as illustrated in FIG. 66, a hole H4 is formed in a region where the contact CC is to be formed. The hole H4 penetrates the insulator 263, the sacrificial member 267, and the stacked structure and reaches the substrate 250. As a result, the substrate 250 is exposed at the bottom of the hole H4. Then, the insulator 209 is formed by oxidizing the portion of the substrate 250 exposed to the bottom portion of the hole H4. Thereafter, the sacrificial members 251 and 252 exposed in the hole H4 are partially removed by, for example, wet etching. As a result, a recess is formed in a portion where each of the sacrificial members 251 and 252 is provided in the hole H4. The sacrificial member 267 is not removed by selective etching of the sacrificial members 251 and 252.

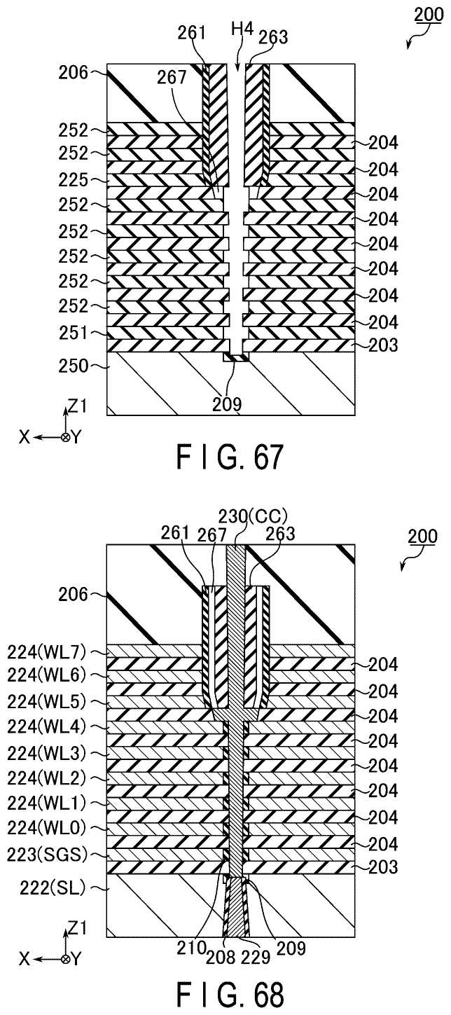

Subsequently, as illustrated in FIG. 67, the sacrificial member 267 exposed in the hole H4 is partially removed by, for example, wet etching. In the hole H4, the sacrificial member 267 is in contact with the sacrificial member corresponding to the wiring layer to be connected to the contact CC. Therefore, the recess formed by removing the sacrificial member in the stacked structure in contact with the sacrificial member 267 and the sacrificial member 267 is larger than the other recesses by the film thickness of the sacrificial member 267 in the Z direction.

Thereafter, as in the fourth modification of the second embodiment, after the hole H4 is embedded by the insulator and the sacrificial member, the process of replacing the stacked wiring structure with the stacked structure is executed. Then, after the sacrificial member in which the hole H4 is embedded and a part of the insulator are removed, the conductor 230 is formed in the obtained space, whereby the contact CC is formed.

Then, as in the second embodiment, the memory device 3 is formed through the process of bonding the circuit chip 300 and the memory chip 100.

### 2.4.5.3 Effects According to Fifth Modification of Second Embodiment

According to the fifth modification of the second embodiment, the sacrificial member 267 includes silicon or silicon oxycarbide. Therefore, the shape of the contact portion of the conductor 230 with the wiring layer can be easily processed.

The sacrificial member 267 is formed by selective growth. With this configuration, the portion of the conductor 230 provided by replacing the sacrificial member 267 is provided so as not to cross the wiring layer on the substrate 303 side with respect to the wiring layer in contact with the conductor 230. Therefore, it is possible to suppress the formation of the conductor in the structure provided between the stacked wiring and the portion of the conductor 230 closer to the substrate 303 than the portion in contact with the corresponding wiring layer. Therefore, an unintended short circuit between the conductor and the wiring layer can be suppressed.

### 2.4.6 Sixth Modification of Second Embodiment

In the fourth modification of the second embodiment, the case where the contact CC and the wiring layer are connected on the side surface has been described, but the present invention is not limited thereto. For example, the contact CC may be connected to the upper surface of the wiring layer. Hereinafter, a configuration and a manufacturing method different from those of the fourth modification of the second embodiment will be mainly described. Description of the same configuration and manufacturing method as those of the fourth modification of the second embodiment will be omitted as appropriate.

FIG. 68 is a cross-sectional view illustrating an example of a cross-sectional structure of a memory device according to a sixth modification of the second embodiment. FIG. 68 corresponds to FIG. 57 in the fourth modification of the second embodiment. Note that the configuration of the portion of the memory chip 100 is also equivalent to the configuration illustrated in FIG. 68.

As illustrated in FIG. 68, according to the sixth modification of the second embodiment, the memory chip 200 includes insulating layers 203, 204, and 206, insulators 208, 209, 210, 261, and 263, a sacrificial member 267, a semiconductor layer 222, wiring layers 223 and 224, and conductors 229 and 230 around the contact CC.

The configurations of the insulating layers 203, 204, and 206, the insulators 208, 209, and 210, the semiconductor layer 222, the wiring layers 223 and 224, and the conductor 229 are the same as those of the second embodiment.

The conductor 230 extends in the Z direction in the hookup region HR and penetrates the stacked wiring structure. One end of the conductor 230 reaches the semiconductor layer 222, for example. The other end of the conductor 230 reaches, for example, above the wiring layer 225 in the Z1 direction. The conductor 230 has a columnar shape and is used as the contact CC.

The insulator 209 is provided between the conductor 230 and the semiconductor layer 222. The insulator 209 includes, for example, silicon oxide. With this configuration, the conductor 230 is electrically insulated from the semiconductor layer 222.

An insulator 210 is provided between the conductor 230 and the corresponding wiring layer and a wiring layer below the corresponding wiring layer in the Z1 direction. With this configuration, the conductor 230 is electrically insulated from the wiring layers below the corresponding wiring layer in the Z1 direction among the wiring layers 223, 224, and 225. In the same layer as the corresponding wiring layer, the conductor 230 is provided away from the wiring layer via the insulator 210.

The conductor 230 is electrically connected to each other by being in contact with the upper surface of the corresponding wiring layer in the Z1 direction. A diameter of a contact portion of the conductor 230 with the corresponding wiring layer is larger than other portions of the conductor 230.

In addition, insulators 261 and 263 and a sacrificial member 267 are provided between the conductor 230 and the stacked wiring structure above the corresponding wiring layer in the Z1 direction.

The insulator 263 surrounds a portion of the side surface of the conductor 230 above the connection portion with the wiring layer in the Z1 direction. The sacrificial member 267 surrounds the side surface of the insulator 263. The insulator 261 surrounds the side surface of the sacrificial member 267. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.6.2 Manufacturing Method

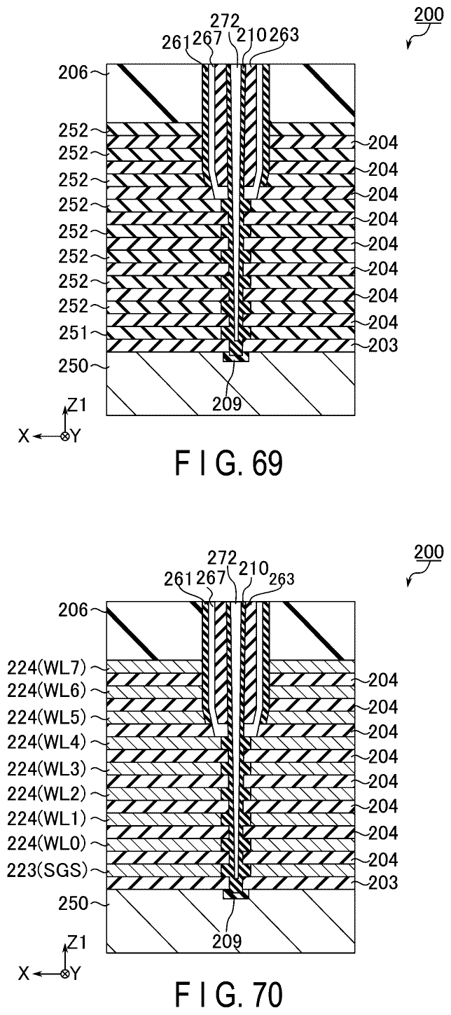

FIGS. 69 to 72 are cross-sectional views illustrating an example of a cross-sectional structure in a process of manufacturing the memory device according to the sixth modification of the second embodiment. FIGS. 69 to 72 correspond to FIG. 68.

First, a structure equivalent to that in FIG. 59 is formed by a process similar to those in the fourth modification of the second embodiment. In other words, the hole H3 is formed in the region where the contact CC is to be formed in the stacked structure. After the insulator 261 is formed in the hole H3, the bottom portion of the hole H3 is etched to expose the sacrificial member immediately below the hole H3. Then, the hole H3 is embedded by forming the sacrificial member 267 and the insulator 263 in the hole H3. Thereafter, a hole reaching the substrate 250 is formed in a region where the contact CC is to be formed. The insulator 209 is formed by oxidizing the portion of the substrate 250 exposed to the bottom of the hole. Then, for example, each of the sacrificial members 251 and 252 exposed in the hole is partially removed by wet etching. As a result, a recess is formed in a portion where each of the sacrificial members 251 and 252 is provided in the hole H4. The sacrificial member 267 is not removed by selective etching of the sacrificial members 251 and 252.

Subsequently, as illustrated in FIG. 69, the insulator 210 and the sacrificial member 272 are formed in this order in the hole, whereby the hole is embedded. In the formation of the insulator 210, each recess is embedded by the insulator 210.

Subsequently, as illustrated in FIG. 70, a replacement process of the stacked structure is executed. As a result, the sacrificial members 251, 252, and 253 are replaced with the wiring layers 223, 224, and 225, respectively. In the replacement process described above, the sacrificial member 267 is not replaced. Therefore, the portion of the wiring layer to be connected to the contact CC is not thickened similarly to the other wiring layers.

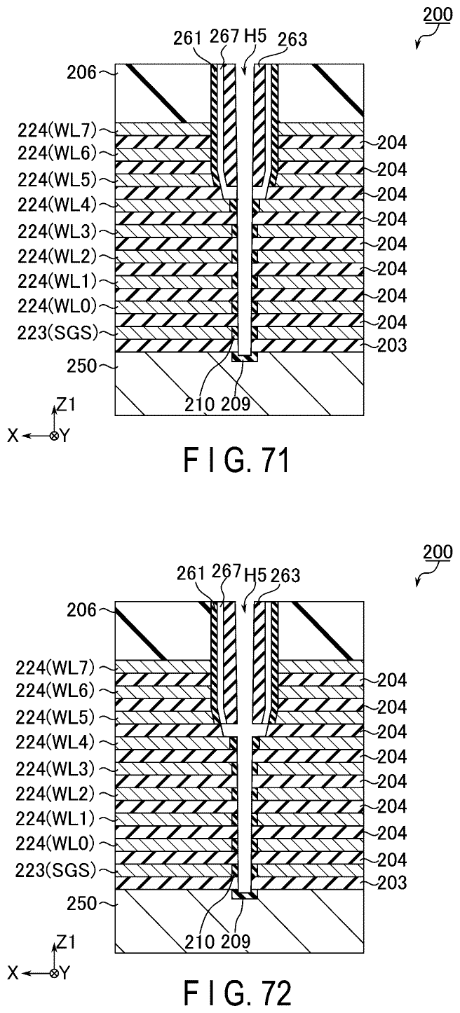

Subsequently, as illustrated in FIG. 71, the sacrificial member 272 is removed to form a hole H5. Then, the insulator 210 is partially removed through the hole H5. In a case where the insulator 210 is removed, the portion of the insulator 210 that fills the recess in the hole H5 remains. On the other hand, the remaining portion of the insulator 210 in the hole H5 is removed. As a result, each wiring layer is not exposed in the hole H5.

Subsequently, as illustrated in FIG. 72, the sacrificial member 267 is partially removed through the hole H5. As a result, in the hole H5, the upper surface of the wiring layer in the Z1 direction is exposed to the space formed by removing the sacrificial member 267.

Thereafter, the inside of the hole H5 is embedded by the conductor 230 to form the contact CC. As a result, the conductor 230 is in contact with the portion exposed in the hole H5 of the corresponding wiring layer. Then, as in the second embodiment, the memory device 3 is formed through the process of bonding the circuit chip 300 and the memory chip 100.

### 2.4.6.3 Effects According to Sixth Modification of Second Embodiment

According to the sixth modification of the second embodiment, the sacrificial member 267 includes silicon or silicon oxycarbide. Therefore, the shape of the contact portion of the conductor 230 with the wiring layer can be easily processed.

In addition, the sacrificial member 267 is in contact with the conductor 230 on the substrate 303 side with respect to the wiring layer in contact with the conductor 230. In this manner, the conductor 230 is provided so as to fill the space from which a part of the sacrificial member 267 has been removed. As a result, the diameter of the conductor 230 at the portion electrically connected to the wiring layer can be made larger than that of the other portions of the conductor 230. Therefore, the conductor 230 can be in contact with the surface of the wiring layer on the substrate 303 side.

### 2.4.7 Seventh Modification of Second Embodiment

In addition, in the sixth modification of the second embodiment, the case where the sacrificial member 267 is formed on the bottom surface and the side surface in the hole H3 and a part thereof is replaced with the conductor 230 has been described, but the present invention is not limited thereto. For example, the sacrificial member 267 may not be provided on the side surface of the hole H3. Hereinafter, a configuration and a manufacturing method different from those of the sixth modification of the second embodiment will be mainly described. Description of the same configuration and manufacturing method as those of the sixth modification of the second embodiment will be omitted as appropriate.

### 2.4.7.1 Cross-Sectional Structure of Memory Device

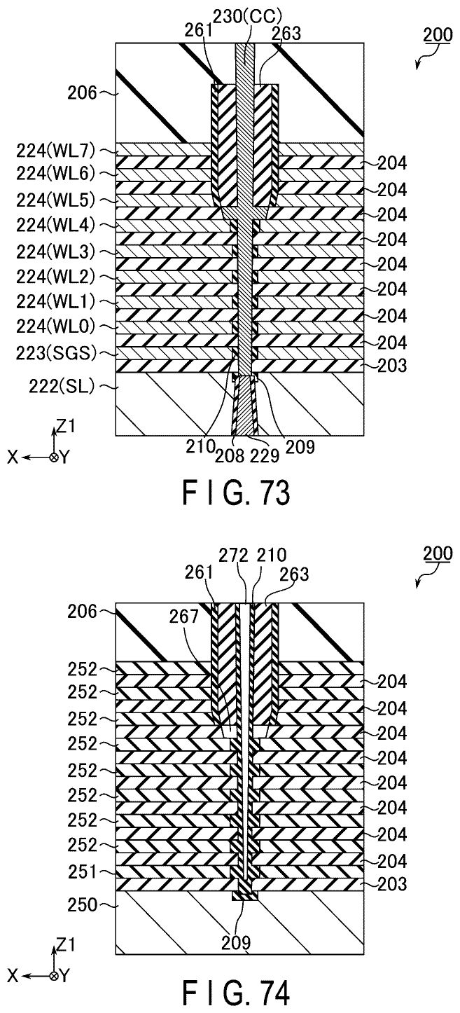

FIG. 73 is a cross-sectional view illustrating an example of a cross-sectional structure of a memory device according to a seventh modification of the second embodiment. FIG. 73 corresponds to FIG. 68 in the sixth modification of the second embodiment. Note that the configuration of the portion of a memory chip 100 is also equivalent to the configuration illustrated in FIG. 73.

As illustrated in FIG. 73, in the seventh modification of the second embodiment, a memory chip 200 includes insulating layers 203, 204, and 206, insulators 208, 209, 210, 261, and 263, a semiconductor layer 222, wiring layers 223 and 224, and conductors 229 and 230 in the vicinity of the contact CC.

The configurations of the insulating layers 203, 204, and 206, the insulators 208, 209, and 210, the semiconductor layer 222, the wiring layers 223 and 224, and the conductors 229 and 230 are the same as those of the fourth modification of the second embodiment.

Insulators 261 and 263 are provided between the conductor 230 and the stacked wiring structure above the corresponding wiring layer in the Z1 direction.

The insulator 263 surrounds a portion of the side surface of the conductor 230 above the connection portion with the wiring layer in the Z1 direction. The insulator 261 surrounds a side surface of the insulator 263. Then, the stacked wiring structure above the wiring layer connected to the conductor 230 in the Z1 direction surrounds the side surface of the insulator 261.

With the above configuration, the conductor 230 is electrically insulated from the lower wiring layers in the Z1 direction from the corresponding wiring layer via the insulator 210, and is electrically insulated from the upper wiring layers via the insulator 261.

### 2.4.7.2 Manufacturing Method

FIGS. 74 to 77 are cross-sectional views illustrating an example of a cross-sectional structure in a process of manufacturing the memory device according to the seventh modification of the second embodiment. FIGS. 74 to 77 correspond to FIG. 73.

First, a structure equivalent to that in FIG. 66 is formed by the same process as in the fifth modification of the second embodiment. That is, a hole is formed in a region of the stacked structure where a contact CC is to be formed. After the insulator 261 is formed in the hole, the bottom of the hole is etched to expose the sacrificial member immediately below the hole. Then, after the sacrificial member 267 is selectively grown in the hole, the inside of the hole is filled with the insulator 263. Thereafter, a hole reaching the substrate 250 is formed in a region where the contact CC is to be formed. The portion of the substrate 250 exposed to the bottom of the hole is oxidized to form the insulator 209. Then, for example, each of the sacrificial members 251 and 252 exposed in the hole is partially removed by wet etching. As a result, a recess is formed in a portion where each of the sacrificial members 251 and 252 is provided in the hole. The sacrificial member 267 is not removed by selective etching of the sacrificial members 251 and 252.

Subsequently, as illustrated in FIG. 74, an insulator 210 and a sacrificial member 272 are formed in this order in the hole, whereby the hole is embedded. In the formation of the insulator 210, each recess is embedded by the insulator 210.

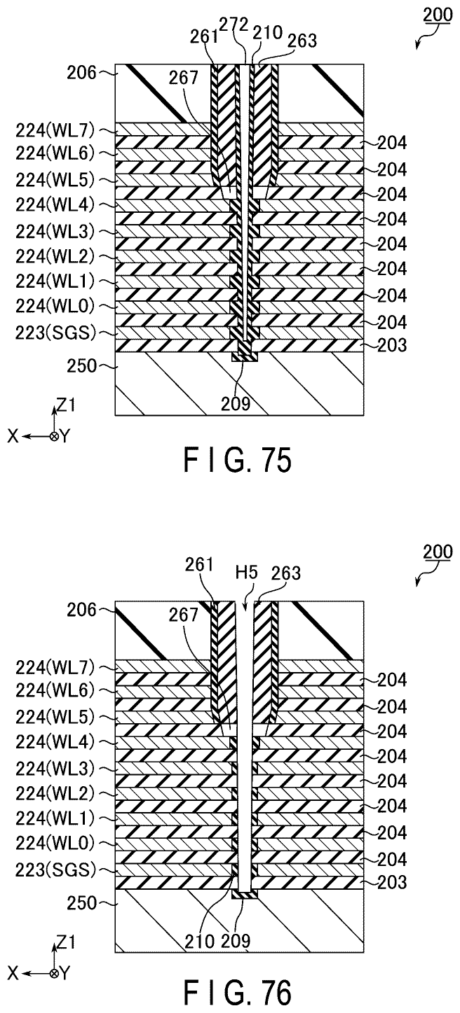

Subsequently, as illustrated in FIG. 75, a replacement process of the stacked structure is executed. As a result, the sacrificial members 251, 252, and 253 are replaced with the wiring layers 223, 224, and 225, respectively. In the replacement process described above, the sacrificial member 267 is not replaced. Therefore, the portion of the wiring layer to be connected to the contact CC is not thickened similarly to the other wiring layers.

Subsequently, as illustrated in FIG. 76, the sacrificial member 272 is removed to form a hole H5. Then, the insulator 210 is partially removed through the hole H5. In a case where the insulator 210 is removed, the portion of the insulator 210 that fills the recess in the hole H5 remains. On the other hand, the remaining portion of the insulator 210 in the hole H5 is removed. As a result, each wiring layer is not exposed in the hole H5.

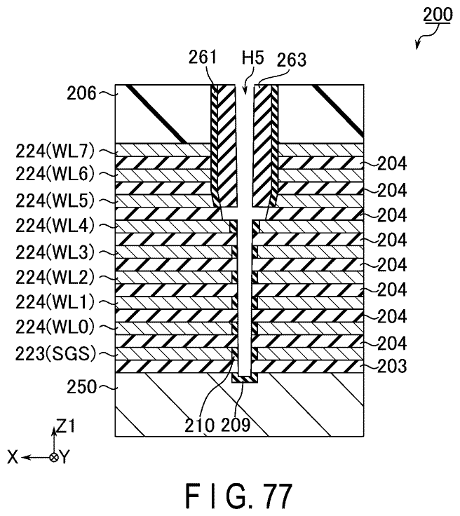

Subsequently, as illustrated in FIG. 77, the sacrificial member 267 is removed through the hole H5. As a result, in the hole H5, the upper surface of the wiring layer in the Z1 direction is exposed to the space formed by removing the sacrificial member 267. In the example of FIG. 77, the sacrificial member 267 is completely removed, but the sacrificial member 267 may partially remain as long as the wiring layer is sufficiently exposed.

Thereafter, the inside of the hole H5 is embedded by the conductor 230 to form the contact CC. As a result, the conductor 230 is in contact with the portion exposed in the hole H5 of the corresponding wiring layer. Then, as in the second embodiment, the memory device 3 is formed through the process of bonding the circuit chip 300 and the memory chip 100.

### 2.4.7.3 Effects According to Seventh Modification of Second Embodiment

According to a seventh modification of the second embodiment, the sacrificial member 267 includes silicon or silicon oxycarbide. Therefore, the shape of the contact portion of the conductor 230 with the wiring layer can be easily processed.

In addition, the sacrificial member 267 is in contact with the conductor 230 on the substrate 303 side with respect to the wiring layer in contact with the conductor 230. In this manner, the conductor 230 is provided so as to fill the space from which a part of the sacrificial member 267 has been removed. As a result, the diameter of the conductor 230 at the portion electrically connected to the wiring layer can be made larger than that of the other portions of the conductor 230. Therefore, the conductor 230 can be in contact with the surface of the wiring layer on the substrate 303 side.

The sacrificial member 267 is formed by selective growth. Therefore, by unintentionally deeply etching the sacrificial member 267, it is possible to suppress formation of a conductor in a structure provided between a portion of the conductor 230 closer to the substrate 303 than a portion in contact with the corresponding wiring layer and the stacked wiring. Therefore, an unintended short circuit between the conductor and the wiring layer can be suppressed.

### 3. Others

Furthermore, in the first embodiment and the second embodiment described above, the case where one hookup region HR is arranged so as to be sandwiched between two memory regions MRa and MRb has been described, but the present invention is not limited thereto. For example, one memory region may be arranged so as to be sandwiched between two hookup regions.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A memory device comprising:
a substrate, a first semiconductor layer, and a second semiconductor layer arranged in this order apart from each other in a first direction;
a plurality of first wiring layers arranged apart from each other in the first direction between the substrate and the first semiconductor layer and including a first layer;
a plurality of second wiring layers arranged apart from each other in the first direction between the first semiconductor layer and the second semiconductor layer and including a second layer;
a first memory pillar extending in the first direction and having portions that intersect the respective first wiring layers and function as memory cells;
a second memory pillar extending in the first direction and having portions that intersect the respective second wiring layers and function as memory cells; and
a first contact extending in the first direction so as to intersect with the first wiring layers, reaching the first semiconductor layer, being in contact with the first layer, being electrically insulated from the first wiring layers excluding the first layer and the first semiconductor layer, and electrically connecting the substrate and the second layer.

2. The memory device according to claim 1, further comprising
a second contact extending in the first direction so as to intersect with the second wiring layers, reaching the second semiconductor layer, being in contact with the second layer, being electrically insulated from the second wiring layers excluding the second layer and the second semiconductor layer, and electrically connecting the second layer and the first contact.

3. The memory device according to claim 1, wherein
each of the first wiring layers has a terrace portion that does not overlap with a wiring layer on the substrate side as viewed in the first direction, and
the first contact is in contact with a terrace portion of the first layer.

4. The memory device according to claim 3, wherein
a film thickness of the terrace portion of the first layer is larger than a film thickness of a portion excluding the terrace portion of the first layer.

5. The memory device according to claim 4, wherein
a diameter of a portion of the first contact that is in contact with the first layer is larger than a diameter of a portion of the first contact that is not in contact with the first layer.

6. The memory device according to claim 1, wherein
a layer of the first wiring layers closer to the substrate than the first layer surrounds a portion of the first contact closer to the substrate than the first layer, as viewed in the first direction.

7. The memory device according to claim 6, wherein
a diameter of a portion of the first contact that is in contact with the first layer is larger than a diameter of a portion of the first contact that is not in contact with the first layer.

8. The memory device according to claim 7, wherein
the first contact is in contact with a side surface of the first layer.

9. The memory device according to claim 8, further comprising
a conductor being in contact with the first contact on a side closer to the substrate than the first layer and being provided continuously with the first layer.

10. The memory device according to claim 9, wherein
the conductor is provided so as to intersect with the layer closer to the substrate than the first layer among the first wiring layers.

11. The memory device according to claim 9, wherein
the conductor is provided so as not to intersect with the layer closer to the substrate than the first layer among the first wiring layers.

12. The memory device according to claim 8, further comprising
a sacrificial member being in contact with the first contact and the first layer on a side closer to the substrate than the first layer,
wherein the sacrificial member includes silicon or silicon oxycarbide.

13. The memory device according to claim 12, wherein
the sacrificial member is provided so as to intersect with the layer closer to the substrate than the first layer among the first wiring layers.

14. The memory device according to claim 12, wherein
the sacrificial member is provided so as not to intersect with the layer closer to the substrate than the first layer among the first wiring layers.

15. The memory device according to claim 7, wherein
the first contact is in contact with a surface of the first layer on the substrate side.

16. The memory device according to claim 15, further comprising
a sacrificial member being in contact with the first contact on a side closer to the substrate than the first layer,
wherein the sacrificial member includes silicon nitride.

17. The memory device according to claim 16, further comprising
an insulator provided between the first contact and the sacrificial member as viewed in the first direction.

18. The memory device according to claim 16, wherein
the sacrificial member is in contact with the first contact across both ends in the first direction.

19. The memory device according to claim 15, further comprising
a sacrificial member being in contact with the first contact on a side closer to the substrate than the first layer,
wherein the sacrificial member includes silicon or silicon oxycarbide.

20. The memory device according to claim 19, further comprising
an insulator provided between the first contact and the sacrificial member as viewed in the first direction.

21. A memory device comprising:
a substrate, a first semiconductor layer, and a second semiconductor layer arranged in this order apart from each other in a first direction;
a plurality of first wiring layers arranged apart from each other in the first direction between the substrate and the first semiconductor layer and including a first layer;
a plurality of second wiring layers arranged apart from each other in the first direction between the first semiconductor layer and the second semiconductor layer and including a second layer;
a first memory pillar extending in the first direction and having portions that intersect the respective first wiring layers and function as memory cells;
a second memory pillar extending in the first direction and having portions that intersect the respective second wiring layers and function as memory cells;
a third contact provided on a surface of the first layer on the substrate side and extending in the first direction; and
a fourth contact extending in the first direction so as to intersect with the first wiring layers, reaching the first semiconductor layer, being electrically connected to the first layer via the third contact, being electrically insulated from the first wiring layers excluding the first layer and the first semiconductor layer, and electrically connecting the substrate and the second layer without interposing the third contact.

22. The memory device according to claim 21, further comprising
a member dividing the first wiring layers into a first portion and a second portion,
wherein the third contact is provided at a position overlapping the first portion and the fourth contact is provided at a position overlapping the second portion as viewed in the first direction.
